(19) United States
(12) Patent Application Publication
(10) Pub. No.: US 2013/0282300 A1
(43) Pub. Date: Oct. 24, 2013

(54) Combined Spectroscopic Method for Rapid Differentiation of Biological Samples

(71) Applicant: Purdue Research Foundation, West Lafayette, IN (US)

(72) Inventors: M. Daniel Raftery, Seattle, WA (US); Huanwen Chen, Zurich (CH); Zhengzheng Pan, West Lafayette, IN (US)

(21) Appl. No.: 13/918,796

(22) Filed: Jun. 14, 2013

Related U.S. Application Data
(63) Continuation of application No. 11/682,408, filed on Mar. 6, 2007, now abandoned.
(60) Provisional application No. 60/779,550, filed on Mar. 6, 2006.

(51) Int. Cl. H01J 49/00; G01R 33/465

(52) U.S. Cl. CPC H01J 49/0036; G01R 33/465
USPC 702/21; 702/19

(57) ABSTRACT

A method for differentiating complex biological samples, each sample having one or more metabolite species. The method comprises producing a mass spectrum by subjecting the sample to a mass spectrometry analysis, the mass spectrum containing individual spectral peaks representative of the one or more metabolite species contained within the sample; subjecting the individual spectral peaks of the mass spectrum to a statistical pattern recognition analysis; identifying the one or more metabolite species contained within the sample by analyzing the individual spectral peaks of the mass spectrum; and assigning the sample into a defined sample class.

### RELATED APPLICATIONS

This application is a continuation of co-pending U.S. patent application Ser. No. 11/682,408 filed Mar. 6, 2007, and claims the benefit of U.S. Provisional Patent Application Ser. No. 60/779,550 filed Mar. 6, 2006; the disclosures of both applications are expressly incorporated herein by reference in their entirety.

This invention was made with government support under grant reference numbers R01 GM58008 and R21 DK070290 awarded by the National Institutes of Health. The Government has certain rights in the invention.

### TECHNICAL FIELD

The present invention is directed toward a method for rapidly differentiating biological samples, and more particularly to the use of high-throughput mass spectrometry and/or nuclear magnetic resonance to differentiate biological samples and to classify such differentiated samples by a multivariate statistical analysis procedure.

### BACKGROUND OF THE INVENTION

Metabolomics is of increasing interest in the life sciences because it offers an approach that gives information on a whole organism's functional integrity over time, including changes following exposure to drugs or toxic/environmental stimulants.^{1, 2} Specific drug-target interactions, biochemical mechanisms and molecular biomarkers can be identified via characteristic changes in the pattern of concentrations of endogenous metabolites in biological fluids or sample tissues.³⁻⁵ Based on the strategies employed in metabolomics-based experiments, subfields have been recognized and classified as metabolite target analysis, profiling, fingerprinting and footprinting.² Detailed background information and applications have been well documented.³⁻⁶

Due to the enormous number of metabolites in a single living system, it is sensible to focus attention on those spectral features that distinguish controls and diseased samples. Various instruments and methodologies have been developed to obtain precise and accurate analytical results for this purpose. It is widely known that mass spectrometry (“MS⁻) and nuclear magnetic resonance (“NMR”) provide the unparalleled ability to analyze complex chemical and biological samples. However, it has only recently been shown that the complex spectra of mixtures can be efficiently analyzed by the addition of multivariate statistical analysis, such as principal component analysis (“PCA”), partial least squares and cluster analysis. For example, NMR and multivariate analysis have been used to differentiate patients with coronary heart disease (see for example, J. Brindle et al., Nature Med. (2002) 8, 1439) and patients with ovarian cancer (K. Odunsi et al., Int. J. Cancer (2005) 113, 782). These approaches, while powerful, can still be improved, as shown by the judicious use of advanced NMR experiments (see for example, P. Sandusky and D. Raftery, Anal. Chem. 77, 2455).

NMR spectroscopy is widely used for sample analysis because it provides a rapid, non-destructive, relatively high-throughput, and quantitative method of chemical analysis that requires minimal sample preparation.⁷ Multivariable statistical analysis, such as PCA, has often been employed to process the data obtained from a set of samples by high resolution NMR.⁸ When coupled to particular separation techniques, mass spectrornmetric analysis of biofluid samples offers much higher sensitivity and better specificity than NMR. Recently developed direct introduction mass spectrometry methods are able to screen hundreds of samples per day, although lengthy sample extraction and preparation methods are normally necessary.⁹ However, a significant challenge is that besides the large signal variance that occurs due to ionization and detection issues, the introduction of chromatographic separation causes additional sample variance. This makes the differentiation of samples due to subtle molecular signatures even more challenging.

Alternative approaches that may be used to differentiate samples include optical spectroscopic analyses, such as FT-IR or Raman spectroscopy.^{10,11} While these techniques provide rapid, non-destructive, reagent-less and high-throughput analysis of a diverse range of sample types, they generally have poorer specificity as compared to mass spectrometry and NMR spectroscopy.

One promising approach to potentially solve some of the above discussed problems is to use MS methods that are able to analyze entire samples without the need for sample separation. For example, the DESI (desorption electrospray ionization) sample introduction method (see for example, Z. Takats et al., Science (2004) 306, 471) can be used to collect a metabolite profile from a surface such as a dried urine sample that has been prepared on paper, plastic or another surface. DESI mass spectrometry is an ambient ionization direct analysis method which provides high sensitivity and high specificity and requires no sample separation and minimal preparation.¹²⁻¹⁵ As an atmospheric ionization technique, DESI is an excellent choice to perform high-throughput analysis.¹³ All of these features make DESI an attractive tool for metabolomics, where the throughput, sensitivity and specificity are highly desirable. On the other hand, many characteristics of DESI remain to be explored, one of them being the matrix effects experienced by the analyte of interest.

The present invention is intended to address and/or to improve upon one or more of the problems discussed above.

### SUMMARY OF THE INVENTION

The present teachings are generally directed to methods for rapidly differentiating biological samples with high-throughput mass spectrometry (MS) and/or nuclear magnetic resonance (NMR). After undergoing MS and/or NMR analyses, the samples can then be classified into various groups, such as “sick” and “healthy” samples. To classify the samples into these groups, a multivariate statistical analysis is utilized.

In other aspects of the present teachings, patient samples are differentiated using MS and/or NMR processes to create a relatively small set of distinguishing molecular species that can be used to classify or cluster the samples into two or more distinct groups. According to this exemplary embodiment, the MS and NMR processes are complementary and lead to a set of molecular components, some of which may be in common, that can be used to differentiate the patient samples. Moreover, the MS data can be used as a metabolic profile snap-shot and can be analyzed without sample separation. While the MS data set is similar to that of the NMR data set, the experimental variance of the NMR data is typically much smaller than that of the MS data. As such, this inherent reproducibility can be used to reduce the sample-to-sample variance and thereby improve the differentiation of the samples.

According to one aspect of the present invention, a method for the parallel identification of multiple endogenous or exogenous molecules of different concentrations or amounts between a first biofluid, tissue or cell sample population and a second population is provided. The method comprises the use of a mass spectrometer and source/inlet system that can analyze a sample without separation. Exemplary systems include, but are not limited to, DESI (Desorption Electrospray Ionization), DART (Direct Analysis in Real Time) and DESI (extractive electrospray ionization). The method also utilizes a statistical pattern recognition process such as, but not limited to, PCA (Principal Component Analysis), PLS (Partial Least Squares), Factor Analysis and any one of a number of supervised multivariate statistical methods.

In certain aspects of the present invention, the parallel identification methods also include data from an NMR (Nuclear Magnetic Resonance) analysis, which is incorporated into the method to expand the number of principal components used to cluster the data. Alternatively, molecular components of the samples that are common to both MS and NMR data sets can be used to separate the samples into different groups or classes. According to this exemplary embodiment, the NMR data can be used to reduce the variance of the MS results by substitution of the NMR-derived concentrations of particularly important species into the statistical analysis in place of the same metabolites detected by MS after suitable scaling to the average MS signal intensity. This approach can be broadened to include additional metabolites that are correlated with the common set of metabolites detected by NMR and MS so as to enhance the detection capability of the approach.

Exemplary NMR experiments according to certain aspects of the present invention include, but are not limited to, one dimensional ′H NMR (1D NMR) experiments, selective Total Correlated Spectroscopy (TOCSY) experiments, or one of any number of suitable 2D or other 1D NMR experiments in common practice and known by those skilled within the art.

In certain aspects of the present invention, the signals from different metabolites in the same metabolic pathway are linked by correlation techniques (e.g., positive correlation and negative correlation) to further improve the ability to separate samples into different classes, such as “normal” or “diseased.” According to these exemplary aspects of the invention, a moderate number of metabolites identified by metabolic pathway information are used for the correlation techniques. These metabolites are then used to carry out a statistical analysis (e.g., PCA or other supervised methods) to reduce the number of input variables. The metabolites used may or may not be correlated according to this exemplary embodiment.

According to another exemplary embodiment of the present invention, a method for differentiating complex biological samples each having one or more metabolite species is provided. According to this embodiment, a mass spectrum is produced by subjecting the sample to a mass spectrometry analysis. The mass spectrum contains individual spectral peaks representative of the one or more metabolite species contained within the sample, and these individual spectral peaks are then subjected to a statistical pattern recognition analysis to identify the one or more metabolite species. After the metabolite species are identified, the sample is then assigned into a defined sample class.

In yet another exemplary embodiment, a method for the parallel identification of one or more metabolite species within complex biological samples is provided. According to this embodiment, a mass spectrum of a sample is produced by subjecting the sample to a mass spectrometry analysis. The mass spectrum contains individual spectral peaks that are representative of the one or more metabolite species contained within the sample. The individual spectral peaks of the mass spectrum are then subjected to a statistical pattern recognition analysis to identify the one or more metabolite species contained within the sample. The sample is further subjected to a nuclear magnetic resonance analysis to reduce sample-to-sample variance as a result of the statistical pattern recognition analysis. The sample is then assigned into a defined sample class.

In still another exemplary embodiment, a method for differentiating complex biological samples is provided including the steps of: subjecting a sample to an electrospray ionization procedure to produce a mass spectrum of the sample, the mass spectrum containing individual spectral peaks representative of one or more metabolite species contained within the sample; performing a principle component analysis on the individual spectral peaks of the mass spectrum to identify the one or more metabolite species contained within the sample; and assigning the sample into a defined sample class.

### BRIEF DESCRIPTION OF THE DRAWINGS

The above-mentioned aspects of the present teachings and the manner of obtaining them will become more apparent and the teachings will be better understood by reference to the following description of the embodiments taken in conjunction with the accompanying drawings, wherein:

FIG. 1 shows representative DESI-MS data from mouse urine recorded without sample preparation, and particularly wherein (a) shows 10 μL, of diluted sample applied to paper and sprayed with methanol/water/acetic acid; and (b) shows DESI-MS/MS spectrum of m/z 214 corresponding to protonated molecular ion of L-aspartyl-4-phosphate;

FIG. 2 shows: (a) the collision-induced dissociation (CID) of authentic glucuronic acid and (b) the CID of peak 195 in sample C1;

FIG. 3 shows the CID spectra of protonated molecular ion of cystathione m/z. 223, wherein (a) represents standard cystathionine, (b) represents peak m/z 223 in C1, and (c) represents peak m/z 223 in C1 with the addition of a cystathione internal standard;

FIG. 4 shows the CID spectrum of (a) the peak m/z 91 in C1 and (b) a mixture of 1,3-dihydroxyacetone and lactic acid;

FIG. 5 shows the monitoring of total ion current (TIC) of a diluted (X1000) urine sample without any separation by: (a) APCI and (b) DESI;

FIG. 6 shows the score plot of data collected for mouse T4 for different surfaces showing clear separation of the data based on the surface used;

FIG. 7 shows PCA score plots for DESI mass spectra recorded using a paper surface and methanol/water/acetic acid as a spray solvent;

FIG. 8 shows: (a) PCA score plots of NMR data obtained with a common set of samples; (b) a loading plot of the first two principal components; (c) a PCA score plot of NMR data using a “reduced compound” data set containing six compounds common to NMR and DESI-MS; and (d) a PCA score plot of DESI-MS data using the “reduced compound” data set containing the same six compounds;

FIG. 9 shows a 3-D score plot combining PCA of NMR and DESI-MS data in accordance with the present teachings;

FIG. 10 shows and exemplary ¹H-NMR spectra of urine from rats with different diets, wherein a) represents a normal diet, b) represents an overnight fast, and c) represents a turkey diet;

FIG. 11 shows exemplary EESI-MS data, wherein the mass spectra was collected using LCQ on 100-fold diluted rat urine samples and with a methanol/water/acetic acid (45:45:10) spray solvent, and wherein a) represents a normal diet, b) represents an overnight fast, and c) represents a turkey diet;

FIG. 12 shows exemplary EESI-MS plots of intensities of a small set of compounds of different samples;

FIG. 13 shows exemplary EESI tandem mass spectra recorded by the CID spectra for the four compounds of FIG. 12;

FIG. 14 shows exemplary mean-centered PCA results for NMR data of rat urine samples, wherein a) represents a score plot with an overall Λ=0.005 and b) represents loading plots for PC1 and PC2;

FIG. 15 shows exemplary plots of mean-centered PCA results for EESI-MS data of rat urine samples recorded using methanol/water/acetic acid as a spray solvent and with five measurements for each sample, particularly wherein a) represents a score plot illustrating reproducibility of the EESI technique and separation of diets with an overall Λ=0.001 and b) represents loading plots for PC1 and PC2;

FIG. 16 shows exemplary 2D loading plots of mean-centered PCA results of EESI-MS data monitoring compounds in a) the UCMAG and b) purine metabolism;

FIG. 17 shows Pearson correlation among a) 19 molecules related to the UCMAG, and b) 42 molecules related to purine metabolism; and

FIG. 18 shows exemplary score plots of mean-centered PCA results of EESI-MS data monitoring compounds in a) the UCMAG and b) purine metabolism.

### DETAILED DESCRIPTION

The embodiments of the present teachings described below are not intended to be exhaustive or to limit the teachings to the precise forms disclosed in the following detailed description. Rather, the embodiments are chosen and described so that others skilled in the art may appreciate and understand the principles and practices of the present teachings.

As stated above, the present teachings are directed to the use of high-throughput mass spectrometry and/or nuclear magnetic resonance to differentiate biological samples and to classify such differentiated samples by a multivariate statistical analysis procedure. Unlike other sampling methodologies that monitor individual metabolite peaks with a mass spectrometer, the present methods analyze the whole spectrum from the sample being analyzed. Despite the presence of hundreds or even thousands of metabolites in the sample, the combination of the MS and NMR processes together with the multivariate statistical pattern recognition approach allows the differentiating signal of samples to be simplified and thereby differentiated into distinct classes.

Exemplary multivariate statistical methods useful in accordance with the present invention include, but are not limited to, PCA, Factor Analysis, and cluster analysis. These methods can be used to identify the differing characteristics of metabolite profiles derived from the mass spectra of different samples. Additionally, supervised methods such as PLS, soft independent modeling of class analogy (“SIMCA”), or neural networks can also be used. These samples may include biofluids (e.g., serum, urine, etc.) tissues, or cells. Sample clustering along one or more of the principle component directions can be used to differentiate classes of samples into groups such as “normal” and “diseased.”

According to one exemplary embodiment of the present invention, a multivariate statistical analysis is individually conducted on the spectra from MS and NMR analyses and then combined in a multidimensional plot to differentiate samples in an n-dimensional space. In yet other exemplary embodiments, a common set of molecular species observed by both MS and NMR analytical techniques are used to differentiate the sample sub-populations. Whatever approach is used, those skilled in the art should understand and appreciate herein that the NMR analysis method has inherently less variance in its measurements. As such, one can substitute the intensities of metabolites in the MS data from each sample with its intensity from the NMR data. The NMR intensities are scaled so that their average is the same as that derived from the MS data. Therefore, a reduction of the overall variance of mass spectrometric measurement process can be made by judicious use of the NMR data, such that one is then able to improve the ability to classify samples based on important biological factors. In addition, this approach can be expanded to include MS-detected metabolites that show correlations. These metabolites can be added to the analysis to help differentiate sample populations while the random variance is kept relatively small.

The NMR methods used can range from simple, one dimensional ¹H NMR (so-called 1D NMR) to frequency selective TOCSY experiments (see for instance, P. Sandusky and D. Raftery, Anal. Chem. (2005) 77, 2455), CPMG-related experiments, or one or more of the many two dimensional NMR experiments in practice. These include 2D-J spectroscopy, HSQC, and numerous others known to those within the art.

One aspect of the present teachings is the ability to correlate metabolite concentrations across known metabolic pathways. For example in the following reaction pathway, metabolite M1 is converted to metabolite M2 via enzyme E1 and to metabolite M3 by enzyme E2:

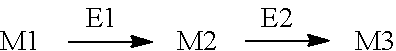

If, for example, enzyme E1 is modified, or down-regulated, then the concentration of M1 will increase as its conversion to M2 is slowed. In contrast, the concentration of M2 will increase because its conversion to M3 by enzyme E2 is largely unaffected. Thus, it can be anticipated that a down-regulation of E1 would result in anti-correlated concentrations of M1 and M2. This information can be very useful to identify specific changes in enzyme function that are related to metabolic changes, such as those that occur in many diseases. This correlation information can be used in part to separate classes of samples or to validate such testing procedures. A result of this observation is that is becomes possible to distinguish different classes of samples by taking ratios of concentrations of the observed, anti-correlated metabolites.

Along these lines, one can use specific metabolic pathway information to limit the number of input variables to the statistical analysis. A problem that can be encountered with multivariate statistics is that when the number of variables is large, the reproducibility of the clustering of samples can be difficult. It is therefore useful to reduce the number of input variables. For example, one could use the largest contributors to the first few principal component (“PC”) loadings. Alternatively, one could use the metabolic pathway information to limit the number of metabolites. For example, using the metabolites from the urea cycle or the pentose phosphate pathway as the input variables to the statistical analysis can be useful in controlling the clustering of the sample data such that disease samples may affect one or more pathways to a greater or lesser extent than other variables, including age, diet, gender, etc.

Applications of this approach include the detection of disease from human or animal biofluids, including, but not limited to, serum, whole blood, plasma and urine, as well as tissue samples that can be analyzed by surface sensitive MS such as Desorption Electrospray Ionization (“DESI”), Direct Analysis in Real Time (“DART”), extractive electrospray ionization (“EESI” see for instance, H. Gu, H. Chen, Z. Pan, A. U. Jackson, N. Talaty, B. Xi, C. Kissinger, C. Duda, D. Mann, D. Raftery, and R. G. Cooks, “Monitoring Diet Effects from Biofluids and Their Implications for Metabolomics Studies,” Anal. Chem. 79, 89-97 (2007), the disclosure of which is incorporated by reference herein), and NMR methods such as magic angle spinning experiments. The methods can be used to study the efficacy of potential drug compounds via metabolism monitoring as is commonly done in pharmaceutical drug trials. Additional applications include the differentiation of liquid food samples, petroleum or petrochemical products, or other samples that are complex in nature due to the multitude of small molecules that are present.

Most methods of multivariate statistical analysis (e.g., PCA) are applicable to processing data obtained by mass spectrometry, as demonstrated by the reported use of PCA for surface imaging and monolayer characterization¹⁶ with TOF-SIMS and biomarker screening using LC-ESI-MS data.¹⁷ In this study, DESI-MS and NMR were used in a demonstration study of differential metabolomics using mouse urine samples without any pretreatment and minimal preparation. Four samples, measured multiple times, corresponding to diseased and healthy mice were well separated in the PCA results. As will be explained in detail below, the small sample set was also used for the present study, which primarily focused on analytical performance, not biological interpretation. Similar PCA score plots were obtained using either the whole NMR or DESI datasets, or a subset of the spectral features associated with those compounds detected by both of the two methods. Peaks in the mass spectra which most readily differentiated the samples were associated with particular compounds which were identified by recording MS/MS data, comparing it with the corresponding data for authentic compounds, and by confirming these conclusions with the NMR data.

According to this exemplary embodiment, desorption electrospray ionization mass spectrometry and nuclear magnetic resonance spectrometry are used to provide data on urine examined without sample preparation to allow differentiation between diseased (lung cancer) and healthy mice. Principal component analysis is used to shortlist compounds with a potential for biomarker screening, and which are responsible for significant differences between control urine samples and samples from diseased animals. Similar PCA score plots have been achieved by DESI-MS and NMR, using a subset of common detected metabolites. The common compounds detected by DESI and NMR have the same changes in sign of their concentrations thereby indicating the usefulness of corroborative analytical methods. The effects of different solvents and surfaces on the DESI-MS spectra are also evaluated and optimized. Over eighty different metabolites are successfully identified by DESI-MS and tandem mass spectrometry experiments, with no prior sample preparation.

Advantages and improvements of the processes and methods of the present invention are demonstrated in the following examples. The examples are illustrative only and are not intended to limit or preclude other embodiments of the invention.

### Example 1

Experimental—Materials and Methods:

Male Balb/c mice weighing 16-18 g were acclimated for 7 days in normal shoebox cages with wood chip bedding prior to inoculation. Then the test mice were dosed with M109 lung tumor cell line¹⁸ suspended in RPMI 1640 with L-glutamine. Mouse serum (1%) was added to the inoculant. Urine samples were collected from the healthy mice (marked as C1 and C3) and the test mice (marked as T2 and T4) for 24 hours. An abscessed tumor was observed on mouse T4 with some blood evident near the tumor. All the mice were weighed before and after inoculation. Urine samples were passed through a 10 kD filter and frozen at −80° C. for further analysis.

Methanol was purchased from Mallinckrodt (Phillipsburg, N.J., USA) and acetic acid and ammonium acetate were purchased from Fisher Scientific (Fair Lawn, N.J., USA). Lactic acid, creatinine, creatine, succinic acid, citric acid, L-aspartyl-4-phosphate, glucuronic acid, cystathione and hippuric acid were purchased from Aldrich (Milwaukee, Wis., USA). Water was purified by using a MilliQ-water system (Millipore, Billerica, Mass., USA). For analysis in the positive ion mode, methanol/water/acetic acid (49:49:2) was used as the spray solvent while for the negative ion mode methanol/water/NH₄OH (50:50:0.1%) was used.

Sample Preparation for DESI-MS:

Samples were diluted by a factor of 1000 and deposited directly onto paper and examined after drying the paper in air for 1-2 minutes. Methanol/water/acetic acid (49:49:2) flowing at a rate of 5 μL/min was used as the spray solvent. To perform PCA, all DESI-MS spectra were recorded at an average rate of 1.5 min per sample and converted into .txt format for further processing. As necessary, negative ion DESI-MS^{I3} spectra were also recorded to confirm the structures of compounds which contributed most to differentiating the urine spectra. To perform MS/MS experiment, ions of interest were isolated with a window width of 1 mass/charge unit and then subjected to collision-induced dissociation (CID) with 25-35% collision energy for 50100 ins.

Instrumentation for DES-MS:

All DESI experiments were carried out using a Thermo Finnigan LTQ (San Jose, Calif.) mass spectrometer fitted with a home-built desorption electrospray ion source which is a prototype for the OmniSpray® Source of Prosolia Inc. (Indianapolis, Ind.). Samples were placed onto a 3D moving stage (Newport, Irvine, Calif.) in order to optimize sample position for analysis. The position of the spray tip of DESI, the surface of the sample, and the front end of the heated capillary of the LTQ were carefully optimized to enhance the signal intensity as in previous studies.¹²⁻¹³

Sample Preparation and Instrumentation for NMR Studies:

For 1H-NMR spectroscopy experiments, 300 μL of urine sample were mixed with 300 μL of 0.5 M potassium phosphate buffer solution in D₂0, pH 7.4, containing 10 mM of TSP (3-(trimethylsilyl) propionic-(2,2,3,3-d4) acid sodium salt) as standard. Spectra were acquired on a Bruker DRX 500 MHz spectrometer equipped with a cryogenic probe using the standard NOESY water presaturation pulse sequence. For each sample, 32 transients were averaged, and 32K data points were acquired using a spectral width of 5000 Hz, Prior to Fourier transformation, a line broadening function equivalent to 0.3 Hz was applied to the free induction decay signal.

Principal Component Analysis (PCA):

PCA was performed directly using the raw data obtained in .txt format in the case of the DESI mass spectra. The H-I NMR spectra were referenced to the TSP singlet at 0 ppm using XWINNMR. Each NMR spectrum was reduced using frequency buckets of 0.035 ppm to reduce the data set size and to compensate for pH and ion concentration dependent shifts of the metabolite signals.⁸ PCA was then performed based on the mean-centered DESI-MS and NMR data using MINITAB 13 (MINITAB Inc., State College, Pa.). Correlation PCA was used for the reduced compound data set. Typically, the first two principal components represent more than 99% of the total variance. Significant differential peaks were shown in the loading plots of PCA results, and the tandem mass spectrometry was performed on these differential peaks in order to identify the corresponding compounds which are potential biomarkers.

Results and Discussion:

Typical DESI-MS Data for Mouse Urine Samples—Positive Ion DESI-MS:

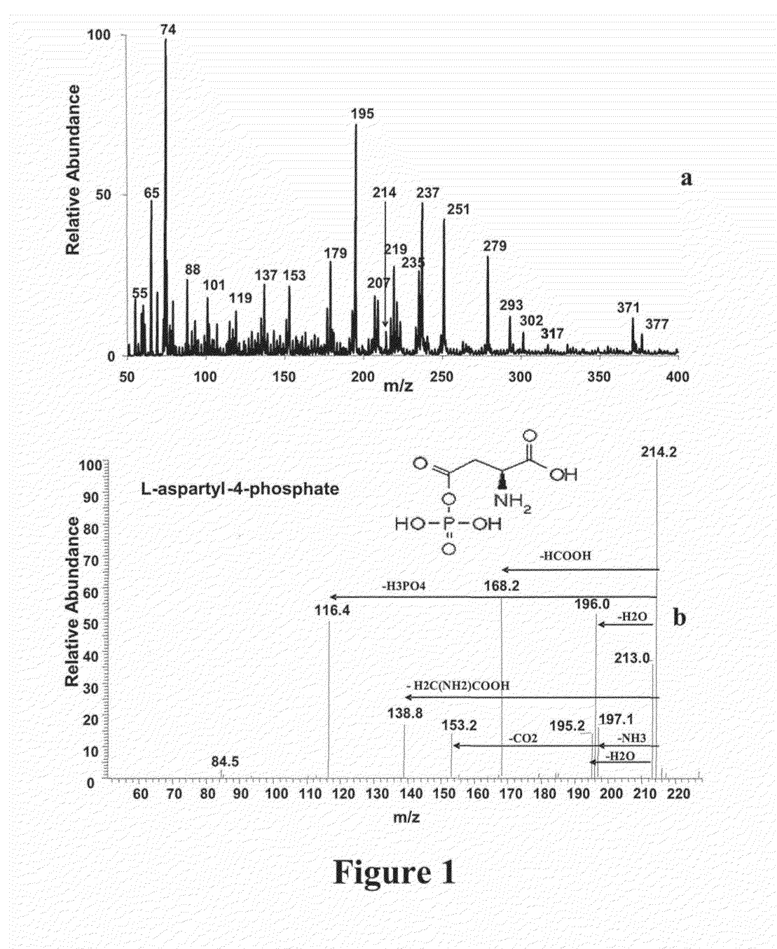

Using the acidic solvent methanol/water/acetic acid (49:49:2), reproducible DESI-MS were recorded (a typical example is shown in FIG. 1a), and pattern recognition analysis was performed using data obtained in different mass/charge ranges. Best results were obtained using a mass/charge range, 50-400 Th.

Identification of Metabolites by Tandem Mass Spectrometry:

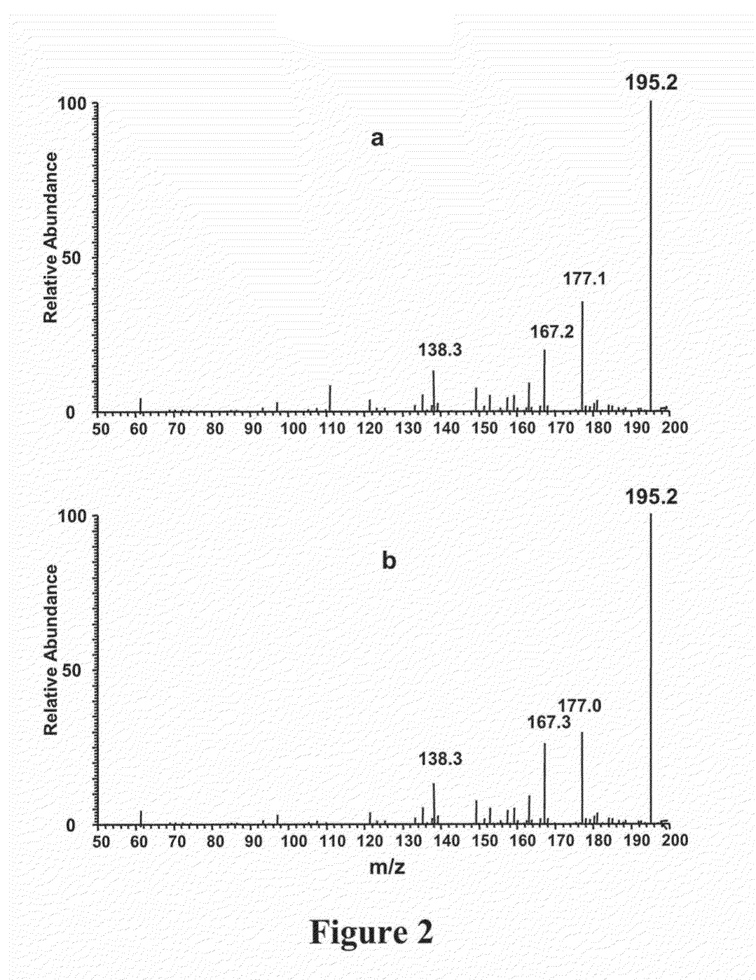

The results reported in this section are for the sample CI using methanol/water/acetic acid (49:49:2) as solvent. To demonstrate the MSⁿ capabilities of DESI-MS, a relatively low abundance peak (m/z 214) in FIG. 1a, sample was isolated and collision-induced dissociation (CID) of this ion was performed in the linear quadrupole ion trap. The product ion CID spectrum is shown in FIG. 1b, the main fragments of m/z 213, 197, 196, 168, 153, 139, 116 are derived from the parent ion by loss of 1, 17, 18, 46, 61, 75, 98 mass units, and these most likely correspond to losses of H, NH₃, H₂O, HCOOH, NH₂COOH, NH₂CH₂COOH and H₃PO₄, respectively. According to the Metlin database,¹⁹ the best matched candidate for the peak of m/z 214 was L-aspartyl-4-phosphate, which is a metabolite of the glycine, serine and threonine metabolic pathways (map00260).^{20,21} Production of a different amount (compared to the normal healthy mice) of metabolites such as L-aspartyl-4-phosphate could be indicative of tumor growth. This assignment was confirmed by recording the CID spectrum of authentic 4-phosphoaspartate (spectrum not shown). A similar experiment is shown in FIGS. 2a and b to confirm the assignment of glucuronic acid to the peak of m/z 195 in the DESI-MS spectrum (FIG. 1a) of sample C1.

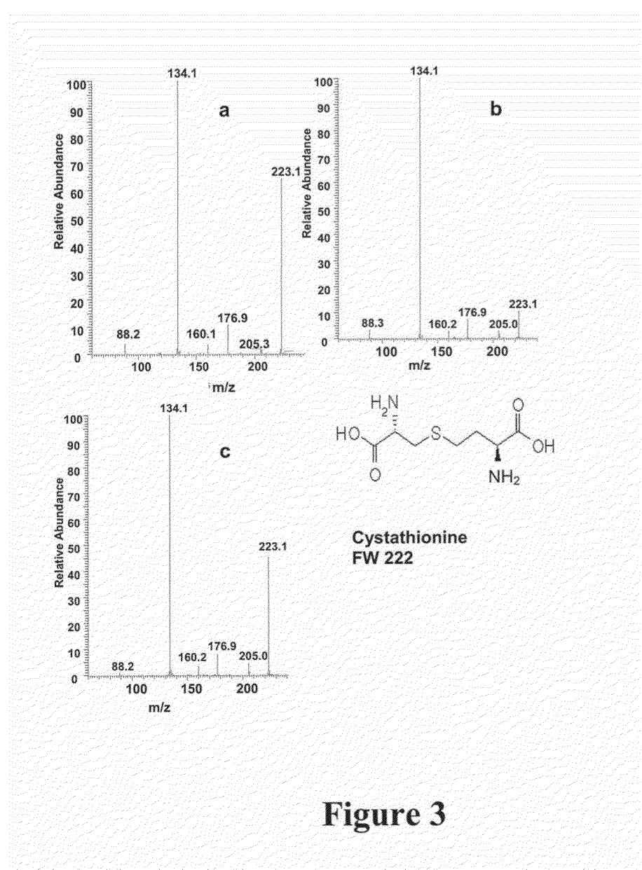

There is a high probability that isomeric compounds will be contained in a single peak in the mass spectrum when a complex sample is not fractionated prior to analysis. In such cases appropriate internal standards could be added to the samples for identification by using tandem mass spectrometry. The relative intensities of the fragments of other isomers should not vary, in the CID spectrum, when only the authentic compound is added. For example, the differential peak of m/z 223 was assigned to cystathionine (FW 222). The CID spectra of the parent ions of m/z 223 of the authentic compound, from C1 without standard addition and with the addition to C1 are shown in FIGS. 3a, b and c, respectively. The fragmentation pattern and the relative intensities of the fragments in FIGS. 3b and c are with the same as that of the authentic compound (FIG. 3a), which provides additional evidence to assign the peak as cystathionine.

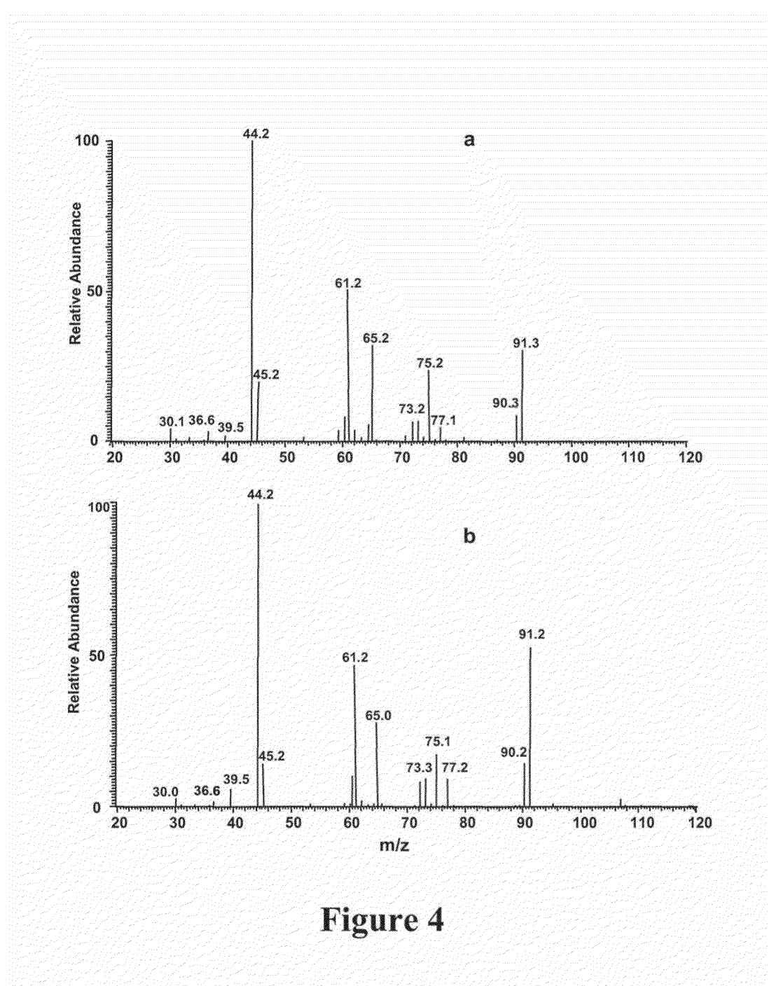

In contrast to the above study where only one isomer was present, the isomers 1,3-dihydroxyacetone and lactic acid could both be present in the urine sample. However, the CID spectrum (data not shown) of neither the 1,3-dihydroxyacetone (FW 90) nor the lactic acid (FW 90) fully matches the CID spectrum of peak m/z 91 in the sample, indicating that probably more than one compound was present. The fragmentation pattern and relative intensities of product ions from the CID spectrum of a mixture of 1,3-dihydroxyacetone with lactic acid (3:1 mol/mol) are in fact a good match to the CID spectrum of the peak m/z 91 from the sample C1 (FIGS. 4a and b). Hence, it can be deduced that both 1,3-dihydroxyacetone and lactic acid were present.

Negative Ion DESI-MS:

Some compounds such as hippuric acid (M=180) were not easy to detect in the positive ion mode even when the standard compound was used directly on paper surface. However, for such samples good quality spectra were invariably obtained in the negative ion detection mode using methanol/water/ammonium hydroxide (50:50:0.1%). The CID spectrum of standard hippuric acid m/z 179 (M-H), gave rise to m/z 105 (C₆H₅CO), 135 (by loss of CO₇) and 119 (C₆H₅COCH₂) as the main fragments, and matched that of the urine sample. Clearly, the negative ion detection mode can also prove useful for identification of some metabolites as an additional tool. The poor positive ionization data can be considered to be the main reason for the poorer differential result for hippuric acid by MS than by NMR studies.

Tolerance to High Salt Samples in DESI when Compared to Other Ionization Methods:

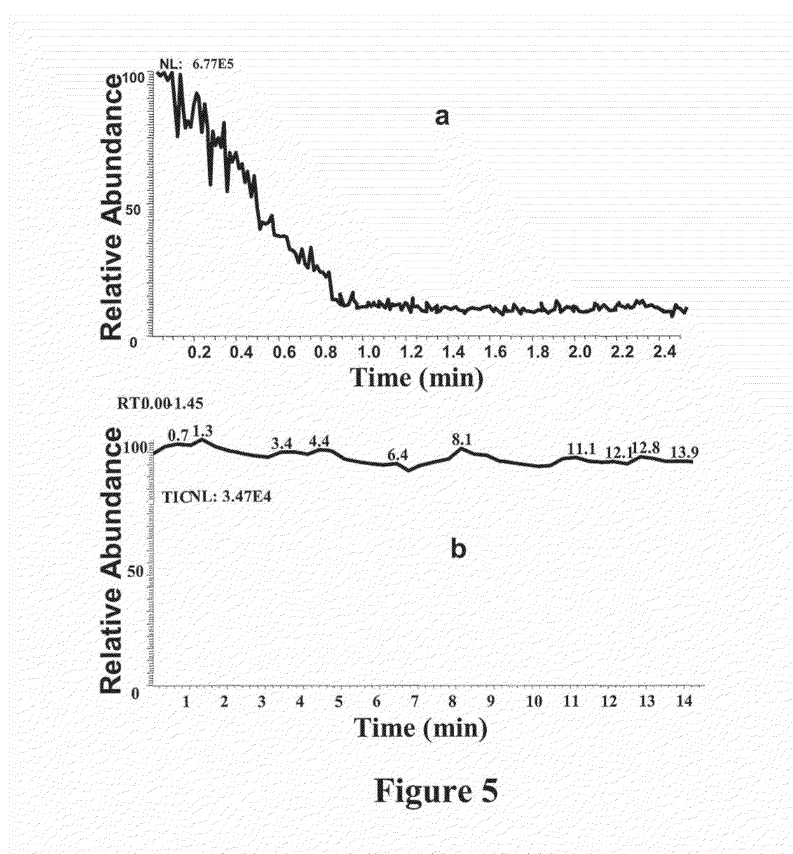

During direct introduction mass spectrometry by ESI/APCI process, the metal cations (e.g. Na, K) contained in the urine sample have a strong tendency to deposit on the surface of the ion transfer lines, particularly in those cases where the samples are directly infused without any separation or desalting, which results in serious carryover effects and a decrease in sensitivity and stability. A typical signal drop observed after 1 minute's operation using APCI at the infusion rate of 1 μL/min is shown in FIG. 5a. A white powder was formed on the surface of sampling capillary due to deposition of organic salts, in DESI, the sample is placed on the surface instead of direct sample infusion; therefore, the tolerance of the DESI source to high salt concentrations is enhanced significantly. This has been demonstrated by obtaining a much more stable signal in contrast to the APCI source using the same sample solution (as shown in FIG. 5b). In contrast to conventional ESI or APCI ion sources, which lose sensitivity rapidly with a significant signal drop (90%) in 1 min when examining urine samples of the same concentration, DESI provides stable signal intensities for long periods of time.

Optimization of DESI Source: Solvent effects in DESI—

Various solvents were evaluated experimentally as the spray solvent in DESI, the acidic solvent, methanol/water/acetic acid (49:49:2) was found to provide more informative and reproducible DESI mass spectra than the neutral or basic solvents. Using pure water or methanol, the signal intensity was much lower than that when using the mixture of methanol and water. This is probably due to the higher surface tension in pure water which results in the formation of bigger droplets. In the pure case of pure methanol, the signal decease was more likely due to the insufficient proton transfer, which is a major route to the generation of secondary ions in positive ion DESI. Compared to the pure solvents, the mixture of both methanol/water (1:1) yielded better signal due to the formation of smaller fine droplets leads to improved protonation and better desolvation. It was found that the basic solvent methanol/water/ammonium hydroxide (50:50:0.1%) produced unstable signals due to the insufficient proton transfer. In contrast, methanol/water/acetic acid (49:49:2) offered better performance than the other solvents examined in positive ion DESI experiments. In the loading plot of PGA obtained using acidic solvent, more peaks were differentiated, indicating that more information could be extracted. This could be explained by the stronger protonation capability of the acidic solvent.

Surface Effects in DESI—

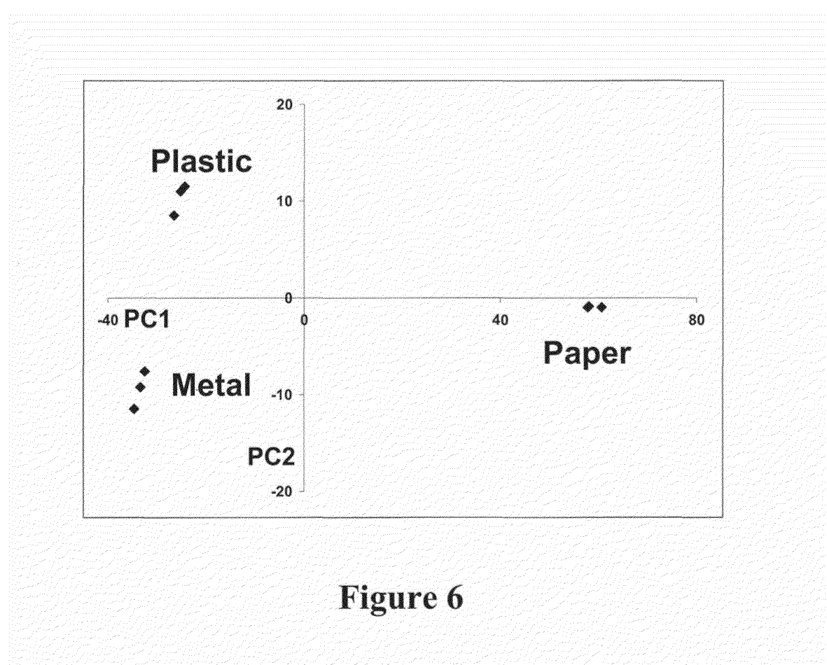

Among the surfaces investigated, filter paper offered the best precision in these measurements although other surfaces, e.g. metal or plastic, also lead to successful sample differentiation using PCA. The score plot obtained with different surfaces show differences in discriminating power. A single urine sample (T4) was selected to investigate the surface effects. From FIG. 6, it can be seen clearly that sample T4 presented different principal components on different surfaces. This phenomenon is ascribed to the non-identical interaction between molecules and surface. For example, the presence of —SH group in molecules such as cysteamine found in the urine sample promotes stronger interactions between the —SH group and metal surface rather than paper surface. Other functional groups, e.g. —NH₂, (COOH, etc, could have similar effect on different surfaces and systematic studies are underway. However, the deviation between spots on the same surface was small; indicating that dependable separation of different samples could be achieved using the same surface. In comparison to other surfaces, paper offered relatively smaller deviations and a more stable signal.

PCA Results:

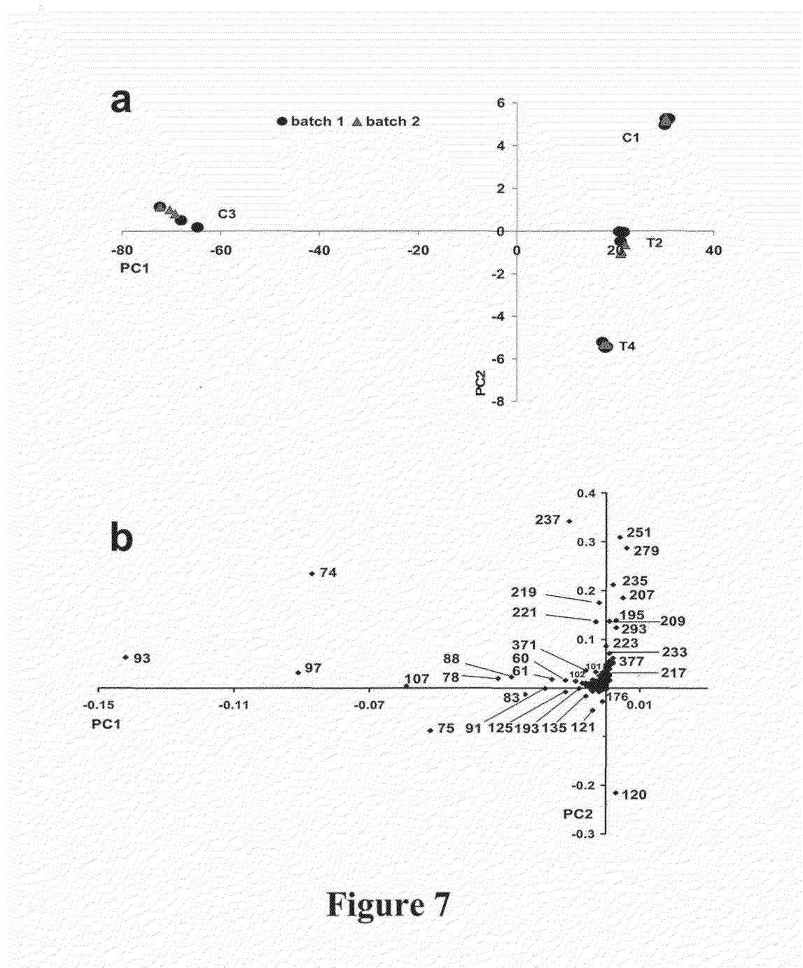

A typical score plot of the PCA results of the DESI-MS spectra obtained from four samples is shown in FIG. 7a. Two DESI runs, (batch 1 and batch 2) were processed. The overlap of the batch 1 and batch 2 PCA data is indicative of the reproducibility of the data. A typical PCA loading plot is shown in FIG. 7b, in which the number represents the m/z value of corresponding ion: urea and acetic acid (61), 3-aminopropanal (74), glyoxylic acid and propionic acid (75), cysteamine (78), urea and sodium cluster (83), 4-aminobutyraldehyde (88), lactic acid and 1,3-dihydroxyacetone (91), glycerol (93), propionic acid/glyoxylic acid sodium cluster (97), glyceric acid (107), glucuronic acid (195), allothreonine (120), melatonin (233), methoxsalen metabolite (237), gamma-glutamylcysteine (251), methoxsalen (217), linolenic acid (279), phenylglycol 3-O-sulfate (235), dimethoxysuccinic acid, dimethylester (207), 3-anthraniloyl-alanine (209), Nacetylserotonin (219), 5-hydroxytryptophan (221), cystathionine (223) and caiteolol (293). All the significant (labeled) peaks in PC1-PC2 space are assumed to be important chemicals differentiating the mass spectra; thus also are potentially useful for biomarker screening. There are approximately 80 compounds in the loading plot, designated by m/z values of their major ions and distributed mainly along PC1 (e.g. 92, 93, 107, 88, etc.) and PC2 (e.g. 237, 251, 279, etc.). The concentrations of compounds corresponding to peaks distributed along PC1 were higher in C3 than in the other samples; similarly, the concentration of the compound(s) responsible for m/z 237 was much higher in C1 than in the other samples. The abundant peaks of m/z 237, 217 are assigned to a protonated metabolite of methoxsalen and to methoxsalen itself, respectively. The latter is a common ingredient in the mouse diet. The relatively high concentrations of these compounds found in C1 indicate that the C1 mice consumed more food than the others, in good agreement with the diet consumption record and the fact that the C1 mouse was the healthiest. A total of eighty compounds, differentiated in terms of intensity, found from the PCA results were identified and validated either by tandem MS or by the analysis of standard compounds (this detailed list is not shown here).

Almost all the compounds found in the DESI experiments are known to be produced in metabolic pathways, such as the glycine, serine and threonine metabolism pathway for example,^{20,22,23} indicating the metabolic origins of these compounds. As another simple example, glycerol (FW 92), an important biological substance,^{24,25} is a metabolite related to the oxygen-scavenger hypothesis in pathway 00262.^{24,26,27} Protonated glycerol was found in this study as a peak at m/z 93, indicating the ability of DESI to identify important metabolites that may differentiate samples.

Confirmation of PCA Results by NMR:

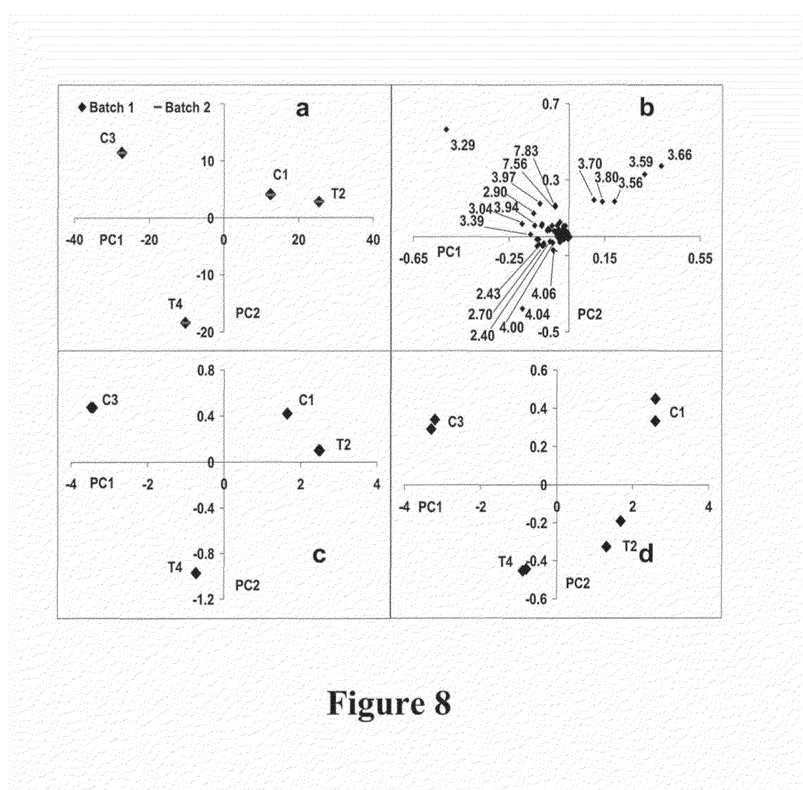

Principal component analysis was carried out using both the aliphatic and aromatic regions within the NMR spectra, 0-9 ppm after the TSP peak at 0 ppm but the region containing HOD and urea peaks (4.5-6 ppm) was removed. FIGS. 8a and b show the score plot and the corresponding loading plot, respectively for comparison with DESI-MS. Four samples are well separated by projection onto the plane of the first two principal components. It is shown in the score plot (FIG. 8a) that samples T4 and C3 are drawn away from samples C1 and T2 mainly by the first principal component (PC 1), indicating an increase of carbohydrates (multiple peaks from 3.50-3.90 ppm), which were also found in the DESI-MS data. With high specificity, these carbohydrates were further classified into carbohydrates of molecular weight 150 (e.g. xylulose, ribose, xylose, arabinose, ribulose) and 182 (e.g. mannitol, glucitol). Similarly, features in the second principal component (PC2), such as taurine, citrate, hippurate and creatine, are observed to increase from sample T4 to C3. Molecules which contribute to the classification can be identified in the loadings. Due to the overlaps in NMR spectra and higher concentration limits required for detection, fewer compounds can be identified with NMR than with DESI-MS. Molecules appearing in both the PC loadings of NMR and DESI-MS are summarized in Table 1. Any chemical changes detected by PCA can be directly related to metabolic pathways for information such as enzymatic changes.

TABLE 1
Compounds from DESI-MS and also by ′H-NMR in mouse urine

| | | | Change from | |
|---|---|---|---|---|
| | | Chemical | mice T4 to Cl by | |
| | Observed ions | shift | Mass | NMR |
| Compounds | (MH⁺) m/z | (ppm)* | Spectrometry | Spectroscopy |
| Acetic Acid | 61 | 2.10(s) | ↓ | ↓ |
| Lactic Acid | 91 | 4.11(q) | ↓ | ↓ |
| | | 1.33(d) | | |
| Creatinine | 114 | 4.05(s) | ↓ | ↓ |
| | | 3.05(s) | | |
| Succinic Acid | 119 | 2.42(s) | ↓ | ↓ |
| Creatine | 132 | 3.94(s) | ↓ | ↓ |
| | | 3.04(s) | | |
| Citric Acid | 193 | 2.72(d) | ↓ | ↓ |
| | | 2.56(d) | | |

Active proton exchanged with deuterium can not be detected (s): singlet; (d): doublet; (q): quartet and (m): multiplet

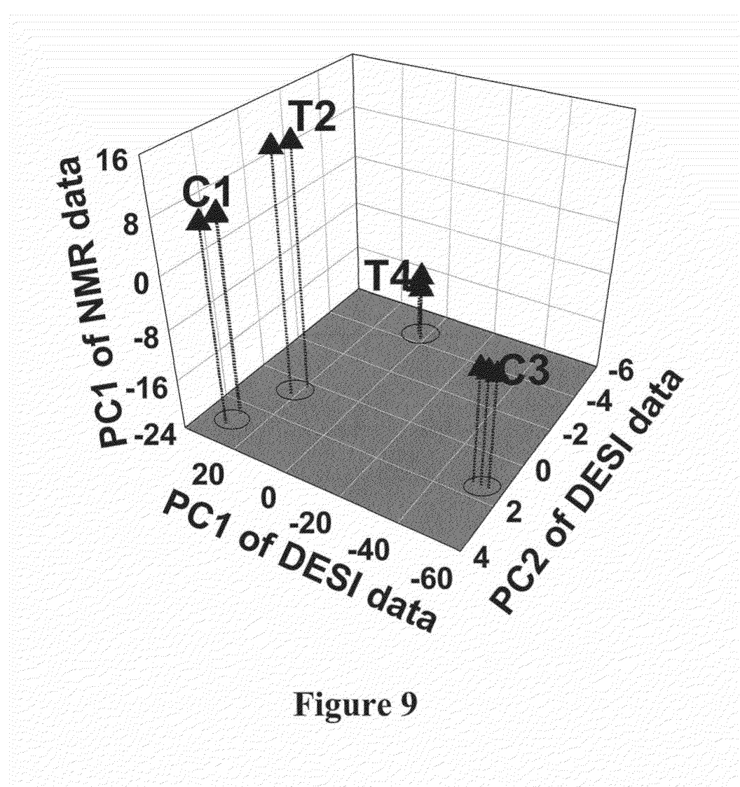

Common Results by DESI-MS and NMR (reduced compound data set): The common compounds detected by both NMR and DESI-MS were isolated and exported for PCA. This alternative approach correlates the NMR and MS data using a “reduced compound” data set. FIGS. 8c and d show that the samples can be distinguished and that the PCA results are very similar to the fuller data sets used in the PCA scores plots shown in FIGS. 7a and 8a. As expected, the common compounds shown in Table 1 have the same changes in sign of their concentrations. It is also possible to combine the scores from NMR and DESI-MS PCA to make a 3-dimensional score plot (FIG. 9). This is so because the PC's of NMR data can be treated as independent to those of DESI-MS data. Thus the PC1 of NMR is added as the third dimension. This may be useful for larger data sets where two-dimensional score plots are insufficient to differentiate the samples. The large number of compounds observable in DESI-MS ensures the consideration of minor components, while NMR analysis is very useful for quantitation and comparisons between different compound classes.

These results indicate that DESI, when combined with multivariate-based statistical pattern recognition methods such as PCA, provide a valuable tool for differential metabonomics using urine. Similar PCA score plots also were achieved with DESI-MS and NMR, using a subset of common detected metabolites, indicating the utility of corroborative analytical methods. The combination of high-throughput,¹³ and sensitive DESI-MS with quantitative NMR spectroscopy and pattern recognition methods provide a promising avenue for the differential detection of biofluid samples, their constituent molecules and eventually for biomarker discovery. Recent work in which exact mass measurements are combined with ambient ionization¹⁵⁻²⁸ promise additional chemical specificity in studies like these. Ambient mass spectrometry is a very active area of research in which modifications to existing methods are being introduced.^{29,30} The subject has recently been reviewed.³¹

### Example 2

The effect of diet on metabolites found in rat urine samples was investigated using nuclear magnetic resonance (NMR) and an ambient ionization mass spectrometry experiment, extractive electrospray ionization mass spectrometry (EESI-MS). [see H. Gu, H. Chen, Z. Pan, A. U. Jackson, N. Talaty, B. Xi, C. Kissinger, C. Duda, D. Mann, D. Raftery, and R. G. Cooks, “Monitoring Diet Effects from Biofluids and Their Implications for Metabolomics Studies,” Anal. Chew., 79, 89-97 (2007), the disclosure of which was previously incorporated by reference]. According to this exemplary example, urine samples from rats with three different dietary regimens were readily distinguished using multivariate statistical analysis on metabolites detected by NMR and MS. To observe the effect of diet on metabolic pathways, metabolites related to specific pathways were also investigated using multivariate statistical analysis. Discrimination was increased by making observations on restricted compound sets. Changes in diet at 24 h intervals led to predictable changes in the spectral data. Principal component analysis (PCA) was used to separate the rats into groups according to different dietary regimens using the full NMR, EESI-MS data, or restricted sets of peaks in the mass spectra corresponding only to metabolites found in the urea cycle and metabolism of amino groups (UCMAG). By contrast, multivariate analysis of variance (MANOVA) from the score plots showed that metabolites of purine metabolism obscure the classification relative to the full metabolite set. These results suggest that it may be possible to reduce the number of statistical variables used by monitoring the biochemical variability of particular pathways. It should also be possible by this procedure to reduce the effect of diet in the biofluid samples for such purposes as disease detection.

Materials and Experiments:

Animal Study and Sample Collection. To assess the influence of diet variations, urine samples were obtained from four male BALB/c rats for three consecutive days. The rats were acclimated for a period of four days before experiments were initiated. Each rat was housed in a metabolism cage with free access to water and rotated daily through the three diets: overnight fast, normal diet (Harlan Teklad 2018 Vegetarian Rodent Diet, 18% protein and 5% fat), and turkey cat food diet (Marsh Gourmet Sliced Turkey in Gravy, Marsh Supermarkets; stored in a refrigerator throughout the course of the study) in a different order for each rat. In total, 12 urine samples were collected and stored at −80° C. until NMR and MS analysis was performed. Rats were treated according to protocols approved by a local Institutional Animal Care and Use Committee (IACUC).

Sample Preparation and Instrumentation for NMR Studies:

A Bruker DRX 500 MHz spectrometer equipped with a room temperature HCN probe was used to acquire one dimensional ¹H spectra. Samples were prepared by mixing 300 μL of undiluted rat urine with 300 μL of 0.5 M potassium phosphate buffer solution (pH 7.4) containing 10 mM of 3-(trimethylsilyl)propionic-(2,2,3,3-d4) acid sodium salt (TSP) in D₂O, which was used as the frequency standard (5=0.00). Water peaks were suppressed using a standard 1D-NOESY (Nuclear Overhauser Effect Spectroscopy) pulse sequence coupled with water presaturation. For each spectrum, 32 transients were collected resulting in 32 k data points using a spectral width of 6000 Hz. An exponential weighting function corresponding to 0.3 Hz line broadening was applied to the free induced decay (FID) before applying Fourier transformation.

After phasing and baseline correction using Bruker's XWINNMR software, NMR spectral regions were binned to 1000 buckets of equal width in order to remove the errors resulting from the small fluctuations of chemical shifts due to pH or ion concentration variations. Cloarec and coworkers have recently reported an alternative approach that utilizes the full-resolution data in order to improve the interpretability of statistical results, although it relies on the supervised statistical method, O-PLS-DA (Orthogonal Projection on Latent Structure Discriminant Analysis).³² The spectral region from 4.5 to 6 ppm was removed to eliminate the variations in the water resonance suppression as well as the urea signal. Each spectrum was normalized by the integration of the whole spectrum. Noise effects were reduced for the datasets by an iterative (threshold-based) approach. All remaining regions were imported into Pirouette software (v. 3.11; InfoMNetrix, Woodinville, Wash.), where mean-centered PCA was performed.

Instrumentation for Extractive Electrospray Ionization Mass Spectrometry Studies:

EESI-MS experiments were carried out using a Thermo Finnigan LCQ (San Jose, Calif.) mass spectrometer coupled with a home-built EESI source.³³ The two sprayers were set in such a manner that both the angle between the sample nebulizer and MS inlet (a) and the angle between the two sprayers ((3) were equal to 90°; this was found to minimize carryover of the urine samples. One hundred-fold diluted urine samples were examined without any further sample pretreatment. Samples were infused at a rate of 1 μL/min by a syringe pump into the sample nebulizer and dispersed under ambient conditions. The spray solvent (methanol/water/acetic acid, 45:45:10) was infused by another syringe pump at an infusion rate of 5 μL/min. Charged solvent droplets were guided into the sample cloud so that analytes could be extracted into the solvent. The resulting droplets were directed into the atmospheric interface of the mass spectrometer where evaporation of the solvent yielded analyte ions for mass analysis. All MS spectra were recorded for exactly 1.5 min and converted into txt format for further statistical processing.

To confirm the structures of those compounds which best differentiated the spectra, collision induced dissociation (CID) was performed in the positive ion detection mode of EESI-MS. To obtain CID spectra, a window of 1.0 m/z units was used to isolate the parent ions and 25-35% (manufacturer's units) collision energy (CE) was applied. To reduce the instability of EESI mass spectra and demonstrate the reproducibility of the technique, five replicate spectra were collected sequentially for each sample.

Similar to the procedure used for the analysis of NMR spectra, the mass spectral region between m/z 100 and 400 was reduced to 1000 buckets of equal width. The data was normalized by integration of each spectrum prior to statistical analysis using Pirouette software. For pathway analysis, mean-centered PCA was applied to 42 compounds known to be associated with the purine metabolism and 19 related to UCMAG with m/z values ranging from m/z 100 to 400. The presence of these compounds in urine samples was confirmed by CID experiments, relevant literature or the METLIN metabolite database.¹⁹

Principal Component Analysis (PCA):

The variability in the spectral profiles was studied by PCA and by multivariate analysis of variance (MANOVA). To give a simple qualitative measurement of the separation of the urine samples, a multivariate normal model was first applied to the scores from the PCA results using the p-value. Wilks' lambda (Λ),³⁴ which in this study is an indicator of the strength of the dietary effect, was also calculated for each full score plot and every two clusters in the score plot. The Wilks' Λ was used as the level of discrimination since the p-values used to test the null hypothesis in MANOVA was less than 0.01 for all score plots. As Wilks' Λ values do not require a normal distribution assumption, which is difficult to verify for this sample size, it is likely to be more appropriate measure of clustering than p-values. Wilks' Λ values less than 0.1 will indicate a stronger treatment effect and thus better clustering. In the current study, MANOVA analysis was performed using the R program (version R 2.2.0).

Results and Discussion:

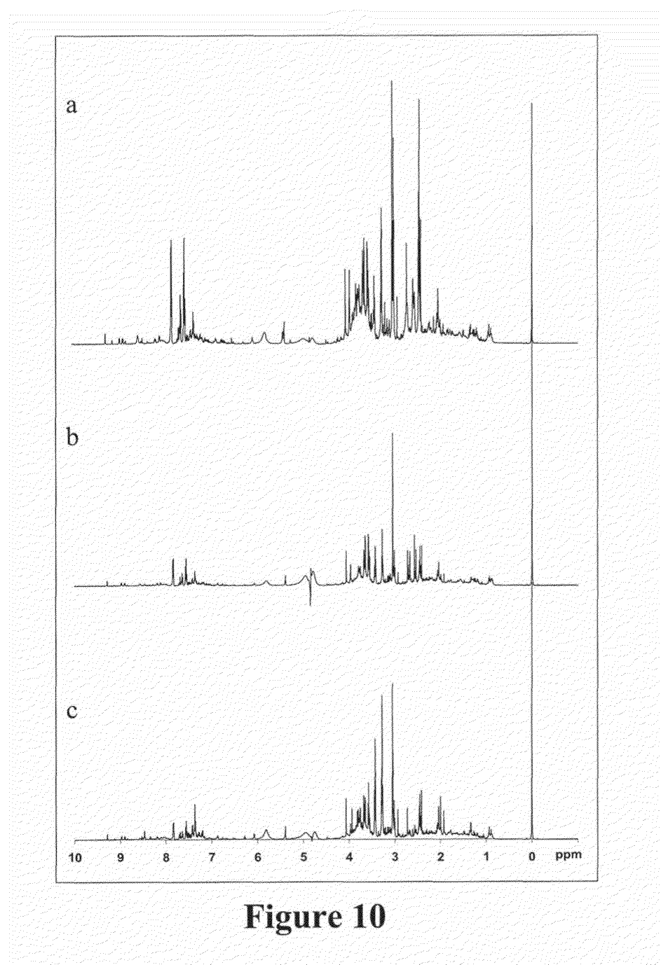

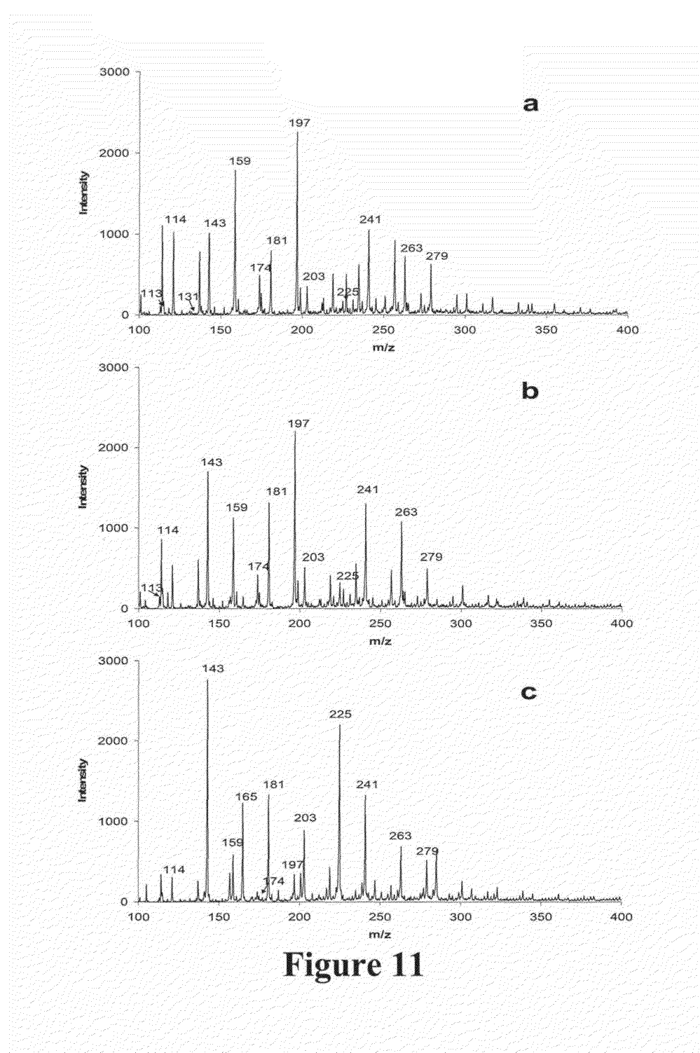

The effect of diet on metabolic composition of rat urine was determined using principal component analysis (PCA) of ¹H NMR and EESI-MS spectra. FIGS. 10 and 11 depict typical ¹H NMR and EESI-MS spectra and illustrate the pronounced variation between the spectra from the three diets. For both techniques the spectra share common features but are still unique to each diet. Application of PCA to each spectrum will identify which metabolites are most influential in causing the observed variations between the spectra.

As shown in FIG. 10, ¹H NMR spectra show a large number of isolated and overlapped peaks caused by the hundreds of metabolites present in the samples. The three spectra in FIG. 10 illustrate the chemical shifts of metabolites which are responsible for the distributions in the score plots of PCA results. In the ¹H NMR spectra, the aliphatic regions are dominated by peaks from trimethylamine oxide (TMAO), taurine, creatinine, glucose, succinate, dimethylamine, and a-ketoglutarate, while hippurate and phenylalanine generate large resonances visible in the aromatic region. These assignments are based on previous work reported in the literature.³⁵⁻³⁶ There is a larger variation in the aliphatic than the aromatic region, therefore, it is anticipated that the aromatic region has a smaller effect on the statistical classification.

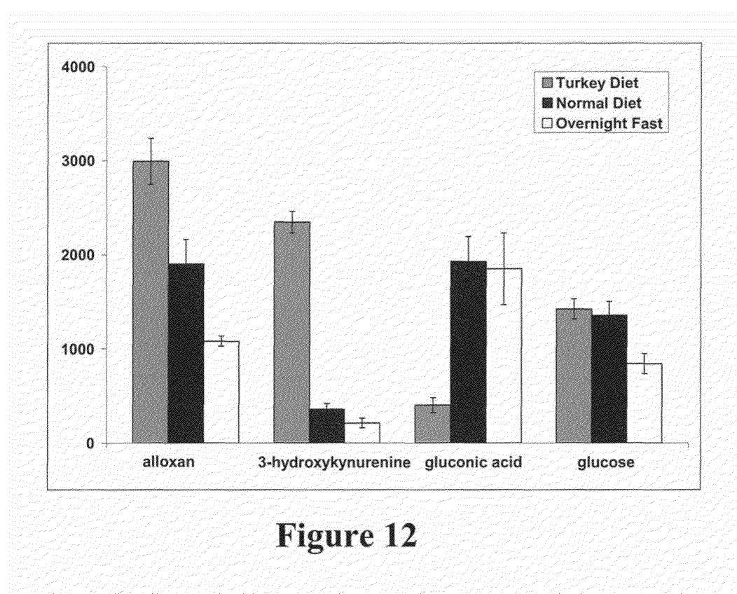

Compared to the NMR spectra, the EESI mass spectra show more variations between the three types of samples. For example, changes in intensities of peaks which are provisionally assigned for creatinine (m/z 114), alloxan (m/z 143), gluconic acid (m/z 197) and 3-hydroxykynurenine (m/z 225) are significant in FIG. 11. For instance, the intensity of the gluconic acid signal, m/z 197, changes by a factor of almost eight (from 2195, 2254, 343, arbitrary units) for the normal, overnight fast and turkey diets respectively. FIG. 12 illustrates this variance in peak intensity for gluconic acid and three other metabolites prominent in each spectrum for the different diets. In FIG. 12, the urine of rats treated with the turkey diet have higher ion abundances for alloxan and 3-hydroxykynurenine, while peaks for gluconic acid are lower for the turkey diet compared to the other two diets. Moreover, for glucose, the difference between rats with different diets is much smaller than for the other compounds. These results are also confirmed by PCA results presented later. The variation between rats fed the same diet is also indicated in FIG. 12 by the size of the corresponding error bars. Overall, these variations among the individual rats are relatively small with the largest variation being observed for alloxan in the turkey and normal diets and gluconic acid in the normal diet and overnight fast.

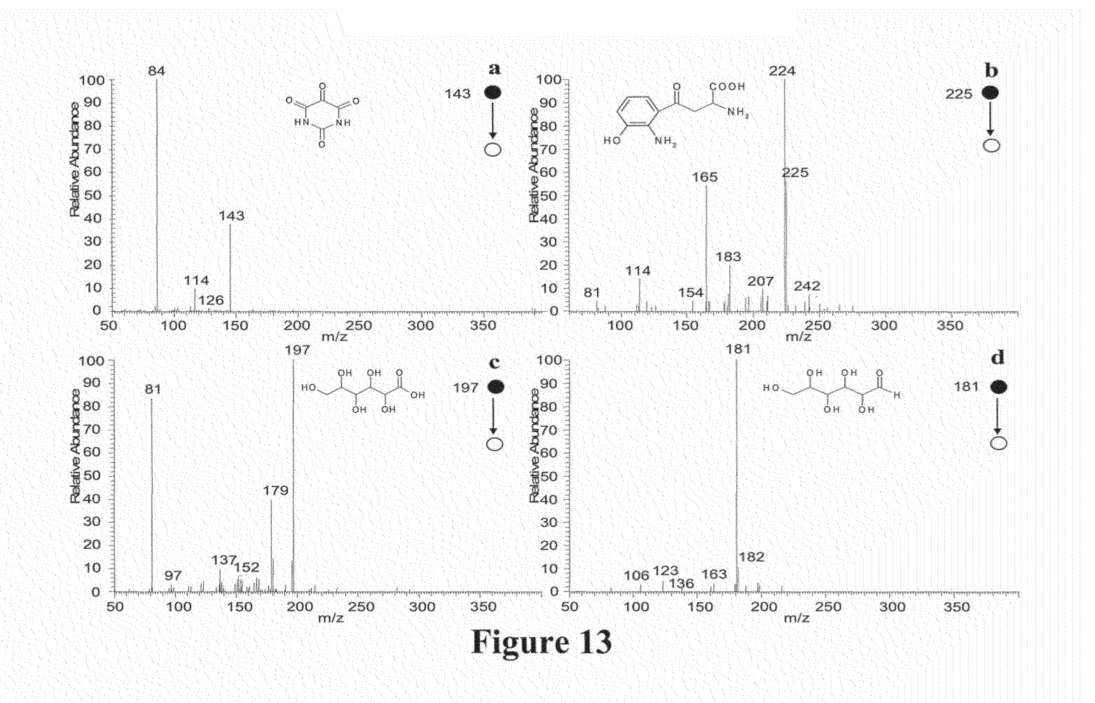

Assignments of peaks which showed pronounced variations in intensities as well as those specific to the purine metabolism and the UCMAG were confirmed through tandem mass spectrometry experiments. FIG. 13 illustrates typical EESI tandem mass spectra recorded by CID spectra for the four compounds in FIG. 12. The CID data were collected at collision energies ranging from 25-35% with a methanol/water/acetic acid (45:45:10) spray solvent in the positive ion mode. For example, the presence of protonated alloxan was confirmed with a standard alloxan solution which showed fragment ions with m/z 143, 126, 114, and 84, corresponding to losses of C₄H₃O₄N₂ (protonated parent ion), OH, COH, and NHCOHNH, respectively.

PCA Results of ¹H-NMR Spectra:

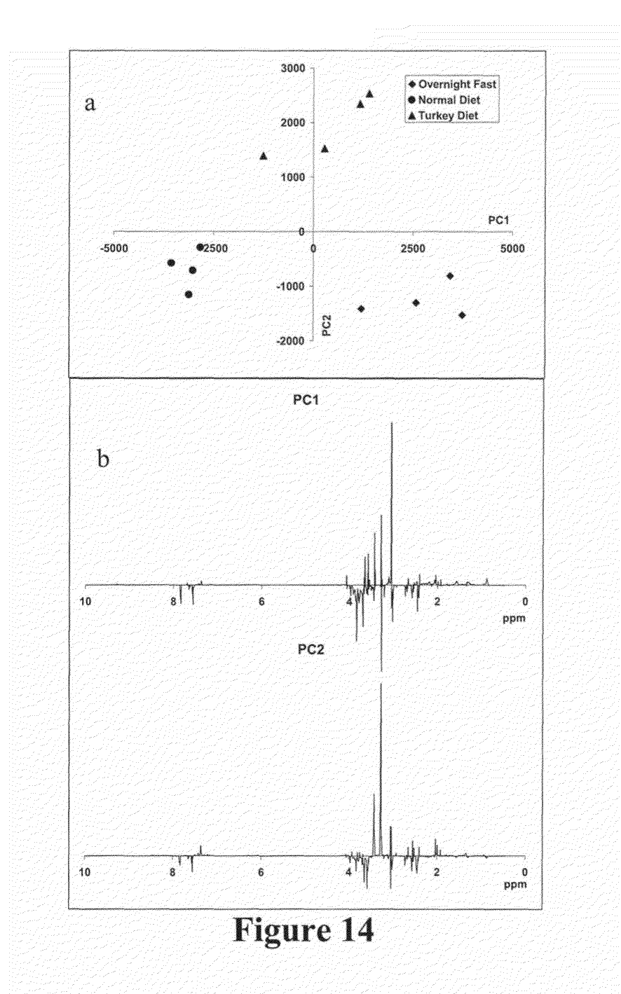

To display the quantitative metabolite variations due to diet and obtain a more accurate analysis, PCA was performed using the full ′H NMR spectra. As shown in FIG. 14a, PCA separated the 12 rat urine samples into three groups according to the dietary treatments in the score plot of PC1 versus PC2. The first two PCs explain more than 90% of the total variance. FIG. 14b, illustrates this variation in 1-D loading plots of PC1 and PC2 resulting from the NMR spectra. The variation within the score plot can be attributed to the alterations of metabolite resonance signals in the NMR spectra. From the two loading plots, the species that are most responsible for differentiation in the NMR spectra, are creatinine (3.05 s), glucose (3.42 t, 3.54 dd), 2-oxoglutarate (2.45 t, 3.01 t), TMAO (3.26 s), and taurine (3.26 t, 3.43 t), which contribute strongly to the aliphatic region. Additional, smaller changes are seen in the aromatic region.

Wilks' Λ values presented in Table 2 represent the quality of the separation or clustering for the score plot of FIG. 14a. The Λ value for spectra within a cluster is 1 since the same diet treatment is being evaluated. Since Λ values are less than 0.1 for the remaining comparisons, it is reasonable to claim that the classification in the score plot is of good quality. Two terms are important for the calculation of Λ values: one is the variation among spectra in each cluster; another is the difference between clusters. The former is determined by many factors such as health, interaction between rats, and the reproducibility of the instrument. However, this teem is expected to be small because the rats chosen were of the same strain and were allowed to interact throughout the study, thus minimizing metabolic differences due to gut microflora.³⁷ In addition, the process of acquiring and processing the data is kept consistent during the study. The latter term, variation between clusters, is expected to be the most influential to the observed classification in the score plot, which is assumed to be determined by the different dietary regimens. The small error bars seen in FIG. 12 add further evidence that these effects are relatively small compared to the observed diet effects.

TABLE 2
Wilks' A for score plot based on NMR spectra*

| | Turkey Diet | Normal Diet | Overnight Fast | Full Plot |
|---|---|---|---|---|
| Turkey Diet | 1 | 0.091 | 0.024 | 0.005 |
| Normal Diet | 0.091 | 1 | 0.047 | |
| Overnight Fast | 0.024 | 0.047 | 1 | |

*See FIG. 14a for score plot.

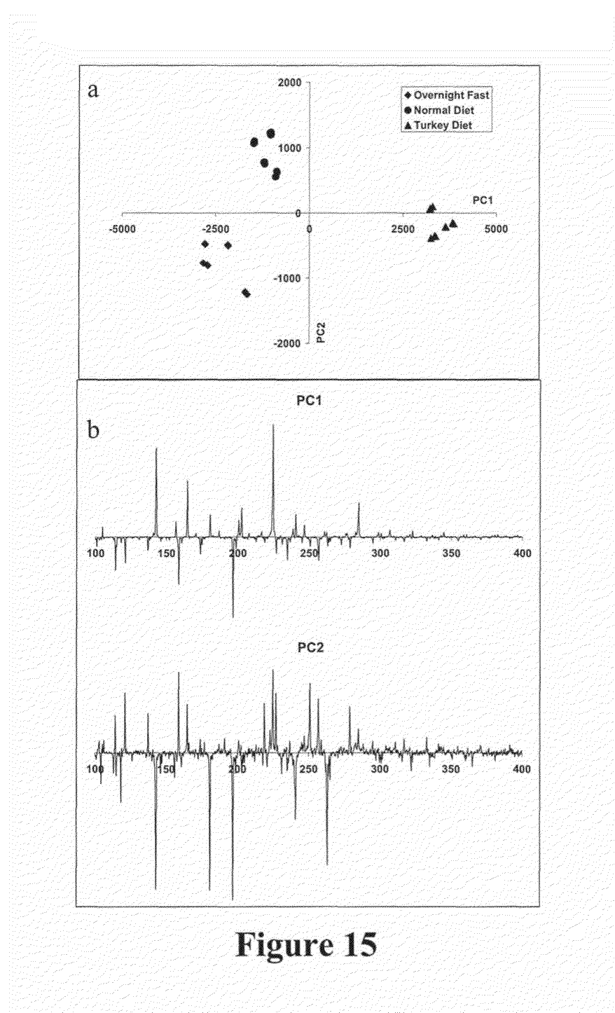

PCA results of extractive electrospray ionization mass spectra: PCA was carried out using the EESI mass spectral data over the m/z range of 100-400, Five replicate measurements were performed for each sample. In FIG. 15a, good reproducibility is indicated; each cluster contains 20 spectra. The reproducibility is evident as the five spectra for each sample are clustered tightly together to give the appearance of fewer data points. Improved classification is obtained when compared with the score plot of the NMR spectra (FIG. 14a). Table 3 gives Λ values for the score plot of the EESI mass spectral data. It is found that FIG. 15a has a somewhat tighter cluster when the same diet is evaluated and better separation between different diets than FIG. 14a which is evident by the smaller Λ values. The high quality separation of diets in FIG. 15a explains the large differences observed for EESI mass spectra of urine samples from rats fed different diets.

TABLE 3
Wilks' A for score plot based on EESI - mass spectra*

| | Turkey Diet | Normal Diet | Overnight Fast | Full Plot |
|---|---|---|---|---|
| Turkey Diet | 1 | 0.010 | 0.009 | 0.001 |
| Normal Diet | 0.010 | 1 | 0.035 | |
| Overnight Fast | 0.009 | 0.035 | 1 | |

*See FIG. 15a for score plot.

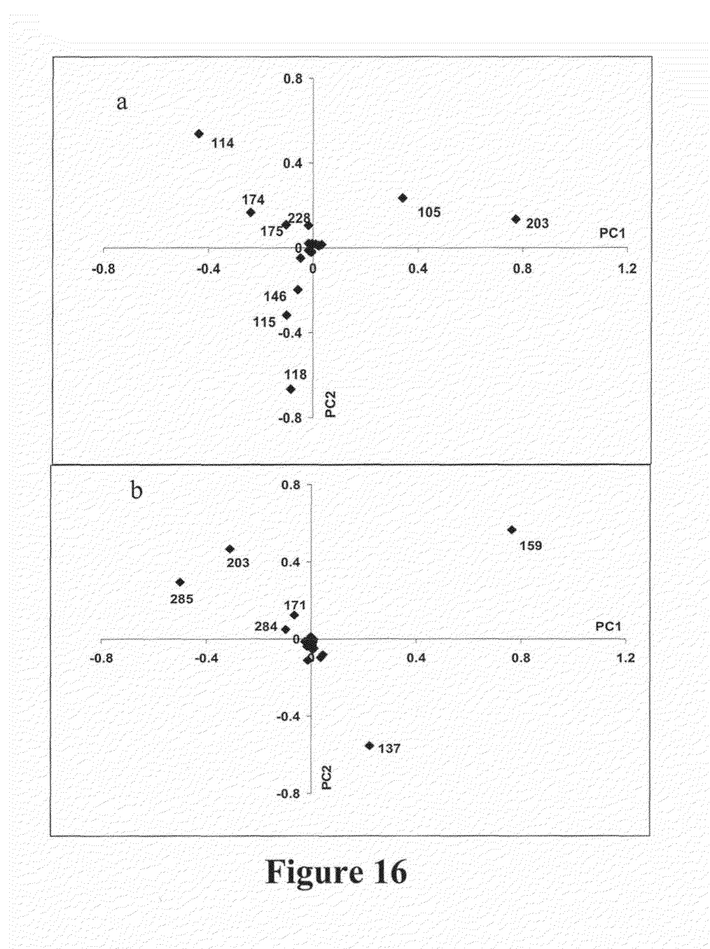

The molecules which contribute most to the spectral patterns were determined using the same methodology as that used for ¹H NMR, and these data are presented in FIG. 15b and Supplemental Information FIG. 16. The principal compounds which show variations in MS include glucose (m/z 181), creatinine (m/z 114), alloxan (m/z 143), gluconic acid (m/z 197), cystine (m/z 240), 3-hydroxykynurenine (m/z 225), γ-1-glutamylcysteine (m/z 251), and carnosine (m/z 227). The concentrations of alloxan, 3-hydroxykynurenine and 5-dihydro-1H-imidazole-5-carboxylate are higher in urine samples from rats on the turkey diet than from rats on the other two diets; conversely, the concentration of urinary gluconic acid is lower from rats on the turkey diet. However, for glucose, the loading value for PC1 is small compared to its PC2 value; thus the effect of PC2 is not negligible even though PC2 contains only 7% of the total variance in the spectra (PC1 explains 85%). The results are in agreement with those presented in FIG. 12; spectra for the turkey diet show higher intensities for ions corresponding to alloxan and 3-hydroxykynurenine and lower intensities for gluconic acid as indicated, while the difference between three diet regimens for glucose are blurred. NMR and EESI-MS give similar clustering. However, with the exception of glucose and creatinine, they select for different information due to their differences in sensitivity, selectivity and detection method. These differences are also complicated by spectral overlaps which are different for the two techniques. However, the results here indicate that the PCA of NMR data and EESI mass spectral data could be cross validated in terms of classification.

PCA of Compounds in the Urea Cycle and Metabolism of Amino Groups and Those Related to Purine Metabolism:

The effect of the three diets was further examined by monitoring compounds associated with specific metabolic pathways. Metabolic pathways are composed of a series of chemical reactions occurring in living systems to generate certain compounds. The concentrations of enzymes that catalyze these reactions can he changed at the gene level by changes induced by diet.³⁸ All the reactants for the pathway reactions come from food intake, either directly or indirectly. As a result, it might be expected that metabolites in some pathways will more strongly express differences induced by diet intake than those associated with other pathways. Purine metabolism and the UCMAG were focused on for this analysis.

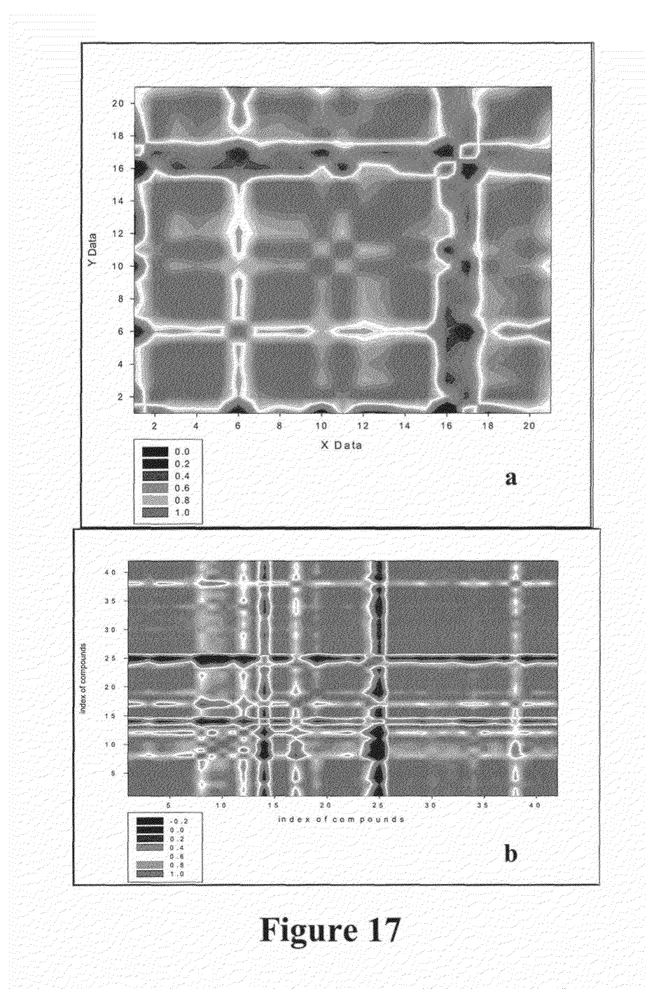

One question one might ask is whether the metabolites in an individual pathway are correlated to each other. The Pearson correlation can be used to address this question.³⁹⁻⁴⁰ The Pearson correlation was calculated for each pair of metabolites identified by MS in each of the two metabolic pathways (19 compounds for UCMAG and 42 for purine metabolism) across the set of 12 urine samples. As is shown in FIG. 17, the Pearson correlation matrices indicate that most of the compounds within each of these two metabolic pathways are highly and positively correlated, and this is especially so for metabolites which are directly linked by enzymes in the pathway. Correlation values above 0.9 are not uncommon. Interestingly, there are several places where there is a negative correlation, and these indicate the possibility of a change in enzymatic activity that couples two negatively correlated metabolites.

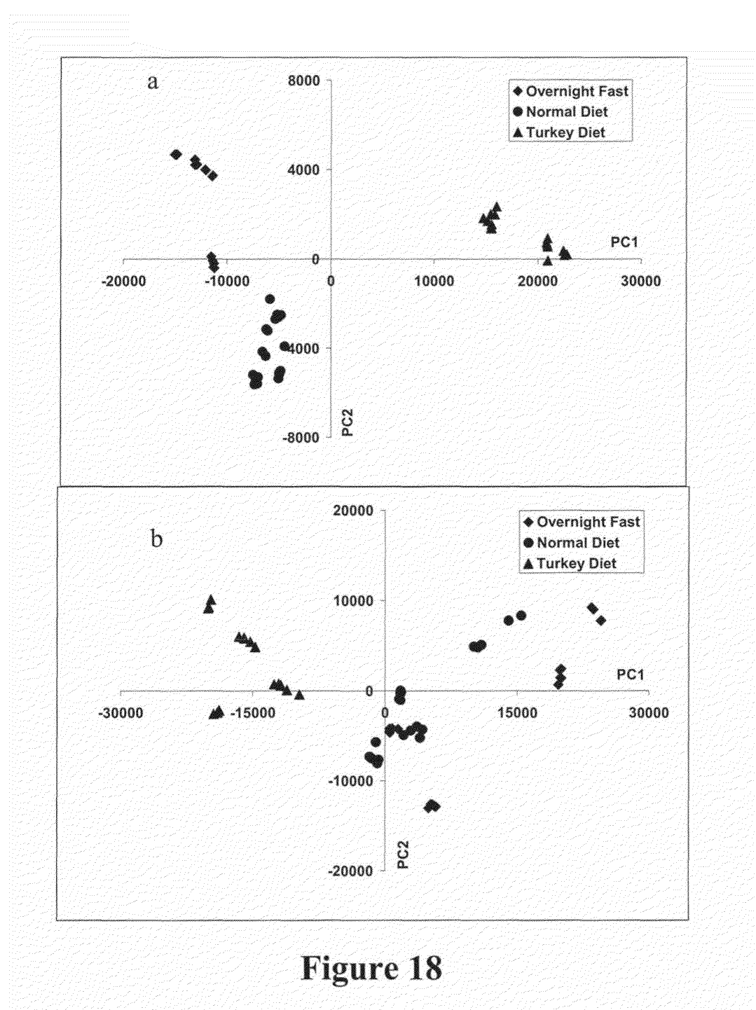

FIG. 18a shows the PCA results for those compounds present in the UCMAG which are responsible for ions with m/z 100-400. In the score plot (FIG. 18a), there are three clusters which follow the diet regimens, similar to the classification that results from the full spectrum analysis. The Wilks' Λ for the reduced score plot (FIG. 18a) is summarized in Table 4; it is shown that the clustering is of good quality although Λ values are slightly higher than for the analysis using the full mass spectra. The loading plot (FIG. 16a) illustrates that creatinine, guanidinoacetate, 5-Dihydro-1-imidazole-5-carboxylate are the main contributing compounds to the classification seen in the score plot. These results suggest that 19 metabolites in the UCMAG are enough to express most of the variations in metabolic profiles caused by different diets.

TABLE 4
Wilks' A for score plot based on PCA of 19 compounds
from the urea pathway*

| | Turkey Diet | Normal Diet | Overnight Fast | Full Plot |
|---|---|---|---|---|
| Turkey Diet | 1 | 0.020 | 0.019 | 0.003 |
| Normal Diet | 0.020 | 1 | 0.093 | |
| Overnight Fast | 0.019 | 0.093 | 1 | |

*See FIG. 18a for score plot.

FIG. 18b shows the PCA results for 42 compounds that are related to purine metabolism and which give ions with m/z 100-400. In the score plot (FIG. 18b), only rats on the turkey diet are separated, while the data points representing the overnight fast and normal diet are mixed. Compared to FIGS. 15a and 15a, FIG. 18b gives the worst separation, as Λ values in Table 5 are larger than 0.1. For example, the level of discrimination between overnight fast and normal diet is 0.48. One point worth noting here is that even the p-value for purine metabolism is less than 0.01, which indicates that the mean values for samples representing the different groups are well separated. The compounds that strongly influence the separation between diets were identified using the loading plot (FIG. 16b). 5-dihydro-1H-imidazole-5-carboxylate, xanthosine and allantoin can separate the turkey diet from the other two diets somewhat but the normal diet and overnight fast diets cannot be differentiated by PCA.

TABLE 5
Wilks' A for score plot based on PCA of 42 compounds
from the purine metabolism′

| | Turkey Diet | Normal Diet | Overnight Fast | Full Plot |
|---|---|---|---|---|
| Turkey Diet | 1 | 0.104 | 0.107 | 0.106 |
| Normal Diet | 0.104 | 1 | 0.478 | |
| Overnight Fast | 0.107 | 0.478 | 1 | |

*See FIG. 18b for score plot.

The present study suggests that metabolites of the UCMAG are more affected by diet compared to metabolites of purine metabolism. Excess nitrogen is converted to urea and removed from the human body by dominant reactions in the UCMAG.^{41, 42} Animals cannot transfer atmospheric nitrogen into forms which can be used by the body and thus diet is the main source for amino acids containing nitrogen which is important in formation of tissues. Currently, dietary alteration is being applied as a clinical treatment for diseases caused by urea cycle defects,⁴³ as well as for a number of genetic metabolic diseases.” Purine metabolism involves the synthetic process of purine and pyrimidine nucleotides.^{41, 45} Indeed, the nutritional requirement for nucleotides is mostly relieved by nucleotide sources within the body, thus it is expected and found that diet will have much less effect on the concentrations of compounds related to purine metabolism.

While exemplary embodiments incorporating the principles of the present teachings have been disclosed hereinabove, the present teachings are not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

### REFERENCES

The following are incorporated herein by reference in their entirety:
1. Nicholson, J. K.; Connelly, J.; Lindon, J. C.; Holmes, E. Nat Rev Drug Discov 2002, 1, 153-161;
2. Dunn, W. B.; Bailey, N. J. C.; Johnson, H. E. Analyst 2005, 130, 606-625;
3. van der Greef, J.; Stroohant, P.; van der Heijden, R. Curr Opin Chem Biol 2.004, 8, 559565;
4. Lindon, J. C.; Holmes, E.; Bollard, M. E.; Stanley, E. G.; Nicholson, J. K. Biomarkers 2004, 9, 1-31;
5. Schmitt-Kopplin, P.; Englmann, M. Electrophoresis 2005, 26, 1209-1220;
6. Griffin, J. L; Bollard, M. E. Curr Drug Metab 2004, 5, 389-398;
7. Reo, N, V. Drug Chem Toxicol 2002, 25, 375-382;
8 Nicholls, A. W.; Holmes, E.; Lindon, J. C.; Shockcor. J. P.; Farrant, R. D.; Haselden, J. N.; Damment, S. J. P.; Waterfield, C. J.; Nicholson, J. K. Chem Res Toxicol 2001, 14, 975-987;
9. Rashed, M. S.; Bucknall M. P.; Little, D.; Awad, A.; Jacob, M.; Alamoudi, M.; Alwattar, M.; Ozand, P. T. Clin Chem 1997, 43, 1129-1141;
10. Goodacre, R. Vib Spectrosc 2003, 32, 33-45;
11. Kell, D. B. Curr Opin Microbiol 2004, 7, 296-307;
12. Takats, Z.; Wiseman, J. M.; Gologan, B.; Cooks, R. G. Science 2004, 306, 471-473;
13. Chen, H. W.; Talaty, N. N.; Takats, Z.; Cooks, R. Anal Chem 2005, 77, 6915 6927;
14. Talaty, N.; Takats. Z.; Cooks, R. G. Analyst 2005, 130, 1624-1633;
15. Williams, J. P.; Scrivens, J. H. Rapid Comrnun. Mass Spectrom. 2005, 19, 3643-3650;
16. Yang, L.; Lua, Y. Y.; Jiang, G. L.; Tyler, B. J.; Linford, M. R. Anal Chem 2005, 77, 4654-4661;
17. Idborg-Bjorkman, H.; Edlund, P. O.; Kvalheim, 0. M.; Schuppe-Koistinen, I.; Jacobsson, S. P. Anal Chem 2003, 75, 4784-4792;
18. Kennedy, M. D.; Jallad, K. N.; Thompson, D. H.; Ben-Amotz, D.; Low, P. S. J Biomned Opt 2003, 8, 636-641;
19. See metlin.scripps.edu;
20. Takahashi, K.; Hayashi, F.; Nishikawa, T. J Neurochern 1997, 69, 1286-1290;
21. Cook, D.; Fowler, S.; Fiehn, 0.; Thomashow, M. F. P Nall Acad Sci USA 2004, 101, 15243-15248;
22. Farfan, M. J.; Calderon, I. L. Enzyme Microb Tech 2000, 26, 763-770;
23. Broeckling, C. D.; Huhman, D. V.; Farag, M. A.; Smith, J. T.; May, G. D.; Mendes, P.; Dixon, R. A.; Sumner, L. W. J Exp Bot 2005, 56, 323-336;
24. Gabaldon, T.; Huynen, M. A. Science 2003, 301, 609-609;
25. Liu, M. Z.; Durfee, T.; Cabrera, J. E.; Zhao, K.; Jin, D. L; Blattner, F. R. J Biol Chem 2005, 280, 15921-15927;
26. Novotny, M. J.; Laughlin, M. H.; Adams, H. R. Am J Physiol 1988, 254, 1-19541962;
27. Homans, D. C.; Asinger, R; Pavek, T.; Crampton, M.; Lindstrom, P.; Peterson, D.; Bache, R. J. Am J Physiol 1992, 263, H392-H398;
28. Cody, R. B.; Laramee, J. A.; Durst, H. D. Anal Chem 2005, 77, 2297-2302;
29. Shiea, J.; Huang, M.-Z.; HSu, H.-J.; Lee, C.-Y.; Yuan, C.-H.; Beech, T.; Sunner, J. Rapid Gommun. Mass Spectrom. 2005, 19, 3701.-3704;
30. Leuthold, L. A.; Mandscheff, J.-F.; Fathi, M.; Giraud, C.; Augsburger, M.; Varesio, E.; Hopfgarner, G. Rapid Commun. Mass Spectrom, 2006, 20, 103-110;
31. Cooks, R. G.; Ouyang, Z.; Takats, Z.; Wiseman, J. M. Science 2006, 311, 1566-1570.
32. Cloarec, 0.; Dumas, M. E.; Trygg, J.; Craig, A.; Barton, R. H.; Lindon, J. C.; Nicholson, J. K.; Holmes, E. Analytical Chemistry 2005, 77, 517-526;
33. Chen, H.; Venter, A.; Cooks, R. G. Chem. Commun. 2006, 2042-2044;
34. Yang, K.; Trewn, J. Multivariate Statistical Methods in Quality Management; McGraw-Hill Companies Inc.: New York, 2004;
35. Constantinou, M. A.; Papakonstantinou, E.; Benaki, D.; Spruill, M. Shulpis, K.; Koupparis, M. A.; Mikros, E. Analytica Chimica Acta 2004, 511, 303-312;
36. Feng, J. H.; Li, X. J.; Pei, F. K.; Chen, X.; Li, S. L.; Nie, Y. X. Analytical Biochemistry 2002, 301, 1-7;
37. Robertson, D. G. Toxicological Sciences 2005, 85, 809-822; 18407-0004
38. Eder, K.; Flader, D.; Hirche, F.; Brandsch, C. Journal of Nutrition 2002, 132, 34003404:
39. Johnson, R. A.; Wichern, D. W. Applied Multivariate Statistical Analysis, 4 ed.; Prentice Hall: Upper Saddle River, N.J., 1998;
40. Kranowski, W. J. Principles of Multivariate Analysis: A User's Perspective Revised ed.; Oxford University Press: Oxford, UK, 2000;
41. Berg, J. M.; Tyrnoczko, J. L.; Stryer, L. Biochemistry, fifth ed.; W. H. Freeman and Company: New York, 2002;
42. Mori, M.; Gotoh, T.; Nagasaki, A.; Takiguchi, M.; Sonoki, T. Journal of Inherited Metabolic Disease 1998, 21, 59-71;
43. Leonard, J. V. Journal of Pediatrics 2001, 138, S40-S44;
44. Pan, Z.; Gu, H.; Talaty, N.; Chen, H. W.; Hainline, B. E.; Cooks, R. G.; Raftery, D. Anal. Bioanal. Chem., in press 2006;
45. Zöllner, N. P. o. t. N. S., 41, 329-342.

What is claimed is:

1. A method for differentiating complex biological samples, each sample having at least two metabolite species, comprising:
producing a mass spectrum by subjecting a complex biological sample without using sample separation techniques to a mass spectrometry analysis, the mass spectrum containing individual spectral peaks representative of the at least two metabolite species contained within the sample;
subjecting the individual spectral peaks of the mass spectrum to a statistical pattern recognition analysis;
identifying at least two metabolite species across known metabolic pathways contained within the sample by analyzing the individual spectral peaks of the mass spectrum;
correlating metabolite concentrations of at least two metabolite species across known metabolic pathways to identify specific changes in enzyme function; and
assigning the complex biological sample into a defined sample class, thereby differentiating the complex biological sample.

2. The method of claim 1, wherein the sample comprises at least one of a biofluid, tissue and cell.

3. The method of claim 1, wherein subjecting the sample to a mass spectrometry analysis comprises subjecting the sample to at least one of a desorption electro spray ionization analysis, a direct analysis in real time (DART) procedure and an extractive electro spray ionization analysis.

4. The method of claim 1, wherein subjecting the individual spectral peaks to a statistical pattern recognition analysis comprises subjecting the peaks to at least one of a principle component analysis, partial least squares analysis, factor analysis and cluster analysis.

5. The method of claim 1, wherein correlating the metabolite concentrations comprises using metabolic pathway information to limit the number of input variables needed to perform the statistical pattern recognition analysis.

6. The method of claim 1, further comprising linking metabolite signals of the one or more metabolite species by a correlation technique, the correlation technique being configured to improve the assignment of the samples into the defined sample class.

7. The method of claim 6, wherein the correlation technique comprises at least one of a positive correlation technique and a negative correlation technique.

8. The method of claim 1, further differentiating the complex biological samples comprising utilizing a nuclear magnetic resonance analysis.

9. The method of claim 8, wherein the nuclear magnetic resonance analysis comprises at least one of a one-dimensional nuclear magnetic resonance analysis and a total correlation spectroscopy analysis.

10. The method of claim 8, further comprising substituting a first intensity value of the one or more metabolite species with a second intensity value, the first intensity value being determined by the mass spectrometry analysis and the second intensity value being determined by the nuclear magnetic resonance analysis.

11. The method of claim 10, wherein substituting the first intensity value with the second intensity value comprises scaling and averaging the second intensity value to equal the first intensity value.

12. The method of claim 1, wherein the defined sample class comprises at least one of a normal metabolite class and a diseased metabolite class.

13. A method for the parallel identification of at least two metabolite species within complex biological samples, comprising:
producing a mass spectrum of a complex biological sample by subjecting the complex biological sample to a mass spectrometry analysis without using sample separation techniques, the mass spectrum containing individual spectral peaks representative of the at least two metabolite species contained within the complex biological sample;
subjecting the individual spectral peaks of the mass spectrum to a statistical pattern recognition analysis to identify the at least two metabolite species contained within the complex biological sample;
subjecting the complex biological sample to a nuclear magnetic resonance analysis, the nuclear magnetic resonance analysis being configured to reduce sample-to-sample variance;
correlating metabolite concentrations of at least two metabolite species across known metabolic pathways to identify specific changes in enzyme function; and
assigning the complex biological sample into a defined sample class; thereby identifying least two metabolite species within complex biological samples in parallel.

14. The method of claim 13, wherein the sample comprises at least one of a biofluid, tissue and cell.

15. The method of claim 13, wherein subjecting the sample to a mass spectrometry analysis comprises subjecting the sample to at least one of a desorption electro spray ionization analysis, a direct analysis in real time (DART) procedure and an extractive electro spray ionization analysis.

16. The method of claim 13, wherein subjecting the individual spectral peaks to a statistical pattern recognition analysis comprises subjecting the peaks to at least one of a principle component analysis, partial least squares analysis, factor analysis and cluster analysis.

17. The method of claim 13, wherein correlating the metabolite concentrations comprises using metabolic pathway information to limit the number of input variables needed to perform the statistical pattern recognition analysis.

18. The method of claim 13, further comprising linking metabolite signals of the one or more metabolite species by a correlation technique, the correlation technique being configured to improve the assignment of the samples into the defined sample class.

19. The method of claim 18, wherein the correlation technique comprises at least one of a positive correlation technique and a negative correlation technique.

20. The method of claim 13, wherein the nuclear magnetic resonance analysis comprises at least one of a one-dimensional nuclear magnetic resonance analysis and a total correlation spectroscopy analysis.

21. The method of claim 13, further comprising substituting a first intensity value of the one or more metabolite species with a second intensity value, the first intensity value being determined by the mass spectrometry analysis and the second intensity value being determined by the nuclear magnetic resonance analysis.

22. The method of claim 21, wherein substituting the first intensity value with the second intensity value comprises scaling and averaging the second intensity value to equal the first intensity value.

23. The method of claim 13, wherein the defined sample class comprises at least one of a normal metabolite class and a diseased metabolite class.

24. The method of claim 13, further comprising using the nuclear magnetic resonance analysis to confirm the identification of the one or more metabolite species.

25. The method of claim 24, further comprising combining the statistical pattern recognition analysis with the nuclear magnetic resonance analysis to create a 3-dimensional score plot, the 3-dimensional plot being configured to improve the confirmation of the one or more metabolite species contained within the sample.

26. A method for differentiating complex biological samples, comprising:
subjecting a complex biological sample to an electro spray ionization procedure without using sample separation techniques to produce a mass spectrum of the complex biological sample, the mass spectrum containing individual spectral peaks representative of one or more metabolite species contained within the sample;
performing a principle component analysis on the individual spectral peaks of the mass spectrum to identify the one or more metabolite species contained within the complex biological sample;
correlating metabolite concentrations of at least two metabolite species across known metabolic pathways to identify specific changes in enzyme function; and
assigning the complex biological sample into a defined sample class; thereby differentiating complex biological samples.

27. The method of claim 26, wherein the sample comprises at least one of a biofluid, tissue and cell.

28. The method of claim 26, further differentiating the complex biological samples comprising utilizing a nuclear magnetic resonance analysis.

29. The method of claim 28, wherein the nuclear magnetic resonance analysis comprises at least one of a one-dimensional nuclear magnetic resonance analysis and a total correlation spectroscopy analysis.

30. The method of claim 26, wherein correlating the metabolite concentrations comprises using metabolic pathway information to limit the number of input variables needed to perform the principle component analysis.

31. The method of claim 26, further comprising linking metabolite signals of the one or more metabolite species by a correlation technique, the correlation technique being configured to improve the assignment of the samples into the defined sample class.

32. The method of claim 31, wherein the correlation technique comprises at least one of a positive correlation technique and a negative correlation technique.

33. The method of claim 26, wherein the defined sample class comprises at least one of a normal metabolite class and a diseased metabolite class.

34. The method of claim 26, wherein the electro spray ionization procedure comprises at least one of a desorption electro spray ionization analysis and an extractive electro spray ionization analysis.
